(19) United States
(12) Patent Application Publication
(10) Pub. No.: US 2026/0074618 A1
(43) Pub. Date: Mar. 12, 2026

(54) VOLTAGE REGULATING CIRCUIT, INDUCTOR ASSEMBLY, AND VOLTAGE REGULATING DEVICE

(71) Applicant: MetaPWR Electronics Co., Ltd., Shanghai (CN)

(72) Inventors: Da Jin, Shanghai (CN); Yahong Xiong, Shanghai (CN); Qinghua Su, Shanghai (CN); Shouyu HONG, Shanghai (CN); Hongxiu Liu, Shanghai (CN)

(73) Assignee: MetaPWR Electronics Co., Ltd., Shanghai (CN)

(21) Appl. No.: 19/321,300

(22) Filed: Sep. 8, 2025

(30) Foreign Application Priority Data
Sep. 10, 2024 (CN) 202411263771.X
Oct. 17, 2024 (CN) 202411454917.9
Dec. 4, 2024 (CN) 202411768957.0
Jan. 26, 2025 (CN) 202510121955.0
Jun. 5, 2025 (CN) 202510747452.4

(51) Int. Cl. H02M 3/155; H01F 17/00; H01F 27/06; H01F 27/26; H01F 27/29; H02M 1/00; H02M 3/00; H02M 3/158

(52) U.S. Cl. CPC H02M 3/1557; H01F 27/26; H01F 27/29; H02M 1/0085; H02M 3/003; H02M 3/1584; H01F 2017/0046; H01F 2027/065

(57) ABSTRACT

The present application provides a voltage regulating circuit. The voltage regulating circuit includes an input positive terminal, an output positive terminal, a ground terminal, N-phase parallel-connected buck circuits, and an additional branch, where N is a natural number greater than 1, and the N output inductors are coupled or uncoupled. The additional branch includes N−1 additional windings coupled to the N−1 inductors and connected in series sequentially and connected in series with one series inductor.

### CROSS-REFERENCE TO RELATED APPLICATION

This application claims the priority benefit of China application serial no. CN202411263771.X filed on Sep. 10, 2024, China application serial no. CN202411454917.9 filed on Oct. 17, 2024, China application serial no. CN202411768957.0 filed on Dec. 4, 2024, China application serial no. CN202510121955.0 filed on Jan. 26, 2025, and China application serial no. CN202510747452.4 filed on Jun. 5, 2025. The entirety of each of the above-mentioned patent application is hereby incorporated by reference herein and made a part of this specification.

### BACKGROUND

### Description of Related Art

In recent years, with the development of technologies such as data center, artificial intelligence, and supercomputers, more and more powerful ASIC chips are used to obtain applications, such as CPU, GPU, machine learning accelerator chip, network switch chip, etc., which consumes a large amount of current, for example, achieving thousands of amperes, and the working current thereof changes rapidly. This load is conventionally supplied using a voltage regulator module (VRM) consisting of a multiphase buck circuit. In order to meet the rapid change of the working current of the ASIC chip, VRM increases the transient response performance of the output voltage of VRM by increasing the number of phases of the multiphase buck circuit and increasing the capacitance of the output decoupling capacitor. However, due to the larger output impedance of the VRM, and the space limitation of the output decoupling capacitor, the conventional VRM is not ideal in terms of output voltage transient response. Other techniques to improve transient response performance of traditional VRM output voltages, such as increasing switching frequency and/or decreasing output inductance values, can improve output voltage transient response performance, but at the expense of reduced efficiency.

Therefore, how to develop a voltage regulating circuit, an inductor component and a voltage regulating device to solve the problems faced by the prior art is an urgent problem in the art.

### SUMMARY

In the view of the above, one of the objectives of the application is to provide A voltage regulating circuit, comprising:
an input positive terminal, an output positive terminal, a ground terminal, N-phase parallel-connected buck circuits, and an additional branch, wherein Nis a natural number greater than 1;
each of the N-phase parallel-connected buck circuits comprises a switch bridge arm and an output inductor; N switch bridge arms are electrically connected in parallel between the input positive terminal and the ground terminal, a first terminal of each output inductor is electrically connected to a midpoint of a bridge arm of a corresponding switch bridge arm, and a second terminal of N output inductors are electrically connected to an output positive terminal;
the additional branch comprises N−1 additional windings and a series inductor, the N−1 additional windings and series inductor are sequentially electrically connected in series; a first additional winding is coupled to a first output inductor, a second additional winding is coupled to a second output inductor, a nth additional winding is coupled to a nth output inductor, wherein n is a natural number, and 1≤n≤N−1; the additional branch is electrically connected in parallel with a Nth output inductor.

Preferably, a first end of each of the additional windings and a first end of the coupled output inductor have the same polarity, and a second end of the (n-1)th additional winding is electrically connected to a first end of the nth additional winding.

Preferably, the N output inductors are coupled in a same inductor magnetic core.

Preferably, the nth additional winding and the nth output inductor are coupled in a same inductor magnetic core.

Preferably, control signals of the N switch bridge arms are sequentially phase-shifted by 360 degrees/N.

Preferably, a coupling coefficient between the output inductor and the additional winding is any value between 0.5 and 1.

Preferably, a coupling coefficient of the N output inductors is any value between −1 and 1.

An inductor assembly, comprising:
an inductor core and an inductor frame, wherein the inductor core includes an upper magnetic cover, a lower magnetic cover, and at least two magnetic columns,
wherein each of the at least two magnetic column is disposed between the upper magnetic cover and the lower magnetic cover; the inductor frame comprises a top surface, a bottom surface, a first side and a third side opposite to each other, a second side and a fourth side opposite to each other, a winding frame and at least two through grooves; the first side, the second side, the third side and the fourth side are disposed between the top surface and the bottom surface; the through groove penetrates through the top surface and the bottom surface;
the winding frame comprises an inductor winding and an additional winding, and the main body of the inductor winding and the main body of the additional winding are wound along the same path;
the inductor frame further includes an electrical connector Vo+, an electrical connector SW, and an electrical connector Sig; the electrical connector Vo+, the electrical connector SW, and the electrical connector Sig are all disposed adjacent to the side surface of the inductor frame; the electrical connector Vo+ forms a Vo+ end portion on the bottom surface of the inductor frame, the electrical connector SW forms a SW end portion on the top surface of the inductor frame, and the electrical connector Sig forms a Sig end portion on the top surface and/or the bottom surface of the inductor frame;
a first end of the inductor winding is electrically connected to an electrical connector SW, a second end of the inductor winding is electrically connected to an electrical connector Vo+, and a first end and a second end of the additional winding are electrically connected to one electrical connector Sig, respectively;
the magnetic column of the inductor magnetic core passes through the through groove, and the upper magnetic cover and the lower magnetic cover are respectively buckled with the winding frame from the top surface and the bottom surface.

Preferably, the inductor frame further comprises a blind groove recessed from a bottom surface of the inductor frame to the winding frame.

Preferably, a depth of the blind groove is greater than or equal to a thickness of the lower magnetic cover.

Preferably, the inductor frame further comprises an independent electrical connector,
wherein one end of the independent electrical connector is fixed on the bottom surface of the inductor frame, the other end of the independent electrical connector is fixed and electrically connected to other components, and the independent electrical connector is configured to transmit power, control signals, or sampling signals.

Preferably, the independent electrical connector is a copper block.

Preferably, the inductor frame further comprises an electrical connector GND, and the electrical connector GND forms a GND end portion at a top surface and a bottom surface of the inductor frame, respectively.

Preferably, the inductor magnetic core comprises two magnetic columns, the through groove is two, and the one inductor winding and the additional winding pass between the two through grooves; the electrical connector GND is disposed on the first side of the inductor frame, the electrical connector Vo+ is disposed adjacent to the third side of the inductor frame, the electrical connector SW is disposed adjacent to the first side of the inductor frame, and the electrical connector Sig is disposed adjacent to the first side and/or the third side of the inductor frame.

Preferably, the inductor magnetic core comprises four magnetic columns, the through groove is four, and the inductor assembly comprises four inductor windings and three additional windings; the one inductor winding and the coupled one additional winding are wound around a through groove; the electrical connector GND, the electrical connector Vo+, the electrical connector SW, and the electrical connector Sig are all disposed adjacent to the first side and the third side of the inductor frame.

Preferably, the inductor magnetic core further comprises a middle column, the inductor frame further comprises a middle column through groove, and the middle column passes through the middle column through groove.

Preferably, the electrical connector GND, the electrical connector SW, the electrical connector Sig and the electrical connector Vo+ are implemented by punching, lateral plating or embedded copper blocks.

Preferably, the electrical connector GND is disposed on the first side and/or the third side of the inductor frame.

Preferably, the inductor frame is implemented by a printed circuit board.

Preferably, one magnetic cover of the inductor magnetic core is a high magnetic permeability material, the other magnetic cover is a low magnetic permeability material, and a ratio of the high magnetic permeability to the low magnetic permeability is greater than 5.

An inductor assembly, comprising:
an upper magnetic cover, a lower magnetic cover, a plurality of winding columns and a plurality of inductor windings,
wherein each inductor winding includes a horizontal winding section and two vertical sections, the two vertical section are a SW section and a Vo+ section, respectively; the upper magnetic cover and the lower magnetic cover are relatively buckled to form a magnetic core, the magnetic core comprises a top surface, a bottom surface and four side surfaces, each horizontal winding section is wound around a winding column respectively between the upper magnetic cover and the lower magnetic cover, and the SW section and the Vo+ section of each inductor winding are respectively disposed on two adjacent side surfaces of the magnetic core; the Vo+ section of each inductor winding is disposed adjacent to the SW section of the next inductor winding; the two ends of the horizontal winding section are respectively provided with two protrusions, the two vertical sections are both provided with through holes, and the two protrusions are cooperatively connected to the through holes.

Preferably, a length of the through hole is greater than or equal to half of a length of the vertical section, and a thickness of the through hole is approximately equal to a thickness of the horizontal winding section.

Preferably, an electrical connection layer is disposed between a surface of the protrusion and a surface of the through hole.

Preferably, a side surface of the protrusion is provided with a micro-protrusion structure.

Preferably, a top end of each of the two protrusions is provided with a chamfer.

Preferably, the upper magnetic cover and the lower magnetic cover respectively adopt a high magnetic permeability material and a low magnetic permeability material, and a ratio of the high magnetic permeability to the low magnetic permeability is greater than 5.

Preferably, the inductor assembly further comprises a middle column, the middle column is disposed among a plurality of winding columns, the horizontal winding section is disposed between the middle column and the winding column.

Preferably, the winding column and the middle column are integrally formed with the upper magnetic cover, and the winding column, the middle column and the upper magnetic cover are made of the same magnetic permeability material, and the lower magnetic cover is made of a different magnetic permeability material;
or, the winding column, the middle column and the lower magnetic cover are integrally formed, the winding column, the middle column and the lower magnetic cover are made of the same magnetic permeability material, and the upper magnetic cover is made of a different magnetic permeability material;
alternatively, the winding columns are integrally formed with one of the magnetic covers, and a first magnetic permeability material is adopted, the middle column is integrally formed with the other magnetic cover, and a second magnetic permeability material is adopted, and the magnetic permeability of the first magnetic permeability material is different from that of the second magnetic permeability material.

A voltage regulating device, comprising:
a first circuit substrate, a second circuit substrate, and an inductor assembly;
wherein the first circuit substrate comprises a through groove, a first pad region, an upper surface and a lower surface opposite to each other, the through groove penetrates through the upper surface and the lower surface, and the first pad region is disposed on the lower surface of the first circuit substrate; the second circuit substrate comprises a second pad region, an upper surface and a lower surface opposite to each other, and the second pad region is disposed on the upper surface of the second circuit substrate;
the inductor assembly comprises an inductor magnetic core, a top surface and a bottom surface opposite to each other, wherein the top surface is provided with at least one top surface end portion, and the bottom surface is provided with at least one bottom surface end portion; the top surface end portion is fixed in the first pad region and is electrically connected to the first circuit substrate; the bottom surface end portion is fixed in the second pad region and is electrically connected to the second circuit substrate; the top surface of the inductor magnetic core is exposed from the top surface of the voltage regulating device by means of a through groove;
wherein the voltage regulating device further comprises a switch bridge arm and a BGA array, the switch bridge arm is disposed on the upper surface of the first circuit substrate, the switch bridge arm is electrically connected to the top surface end portion through the first circuit substrate and the first pad region; the BGA array is disposed on the lower surface of the second circuit substrate, the BGA array is electrically connected to the bottom surface end portion through the second circuit substrate and the second pad region.

Preferably, vertical projections of the switch bridge arm and the inductor magnetic core on the same horizontal plane do not overlap.

Preferably, the top surface end portion is a SW end portion, and the SW end portion is electrically connected to a midpoint of a bridge arm of the switch bridge arm; the bottom surface end portion is a Vo+ end portion, and the Vo+ end portion is electrically connected to a portion of the BGA array.

Preferably, the inductor assembly further comprises an electrical connector GND, the electrical connector GND is disposed on a side surface of the inductor assembly by side copper plating, and a GND end portion is formed on the top surface and the bottom surface of the inductor assembly.

Preferably, the inductor assembly further comprises an electrical connector Sig, and the electrical connector Sig forms a Sig end portion on the top surface and/or the bottom surface of the inductor assembly.

Preferably, further comprising a series inductor disposed adjacent to the inductor assembly and electrically connected to the Sig end portion.

Preferably, further comprising an independent electrical connector, wherein one end of the independent electrical connector is fixed to and electrically connected to the first circuit substrate, and the other end of the independent electrical connector is fixed to and electrically connected to the second circuit substrate.

Preferably, further comprising an input capacitor, wherein the input capacitor is disposed on the upper surface and/or the lower surface of the first circuit substrate.

Preferably, further comprising an output capacitor, wherein the output capacitor is disposed on the upper surface of the second circuit substrate.

Preferably, the output capacitor is disposed on the upper surface of the second circuit substrate and corresponds to a lower surface of the inductor assembly.

A voltage regulating device, comprising:
at least three voltage regulating units, which are a left-side voltage regulating unit, an intermediate voltage regulating unit and a right-side voltage regulating unit, respectively;
wherein each of the voltage regulating units comprises a bridge arm unit, an inductor assembly and a BGA unit, and the bridge arm unit, the inductor assembly and the BGA unit in each of the voltage regulating units are electrically connected;
the bridge arm unit, the inductor assembly, and the BGA unit of the left-side voltage regulating unit are sequentially stacked in a vertical direction; the bridge arm unit, the inductor assembly, and the BGA unit of the right-side voltage regulating unit are sequentially stacked in a vertical direction; the bridge arm unit and the inductor assembly of the intermediate voltage regulating unit are stacked in a vertical direction; the bridge arm unit of the intermediate voltage regulating unit is arranged between the left side bridge arm unit and the right side bridge arm unit, the inductor assembly of the intermediate voltage regulating unit is arranged between the inductor assembly of the left side voltage regulating unit and the inductor assembly of the right side voltage regulating unit; the BGA unit of the intermediate voltage regulating unit surrounds the BGA unit of the left side voltage regulating unit and the BGA unit of the right side voltage regulating unit.

Preferably, further comprising a first circuit substrate and a second circuit substrate, wherein the first circuit substrate and the second circuit substrate both comprise an upper surface and a lower surface opposite to each other; the bridge arm unit is disposed on the upper surface of the first circuit substrate, the inductor assembly is disposed between the lower surface of the first circuit substrate and the upper surface of the second circuit substrate, and the bridge arm unit and the inductor assembly are electrically connected through the first circuit substrate;
the BGA unit is disposed on the lower surface of the second circuit substrate, and the inductor assembly and the BGA unit are electrically connected through the second circuit substrate.

Preferably, the bridge arm unit comprises four switch bridge arms, each of the switch bridge arms comprises a pin SW and a pin Sig, and the pin SW and the pin Sig are arranged on two opposite sides of each switch bridge arm; the inductor assembly includes a magnetic core and a winding, a vertical projection plane of the magnetic core is on a horizontal plane where the bridge arm unit is located, and each of the pins SW is disposed along an outer side of the vertical projection plane.

Preferably, the four switch bridge arms are respectively a first switch bridge arm, a second switch bridge arm, a third switch bridge arm, and a fourth switch bridge arm, the pins Sig of the first switch bridge arm and the third switch bridge arm are arranged adjacent to each other, and both are in the vertical projection plane; and the pins Sig of the second switch bridge arm and the third switch bridge arm are both arranged outside the vertical projection plane.

Preferably, further comprising a Vin+ electrical connector, a GND electrical connector, and a Sig electrical connector; the Vin+ electrical connector, the GND electrical connector and the Sig electrical connector are disposed between the first circuit substrate and the second circuit substrate and are used for transferring power and signals between the first circuit substrate and the second circuit substrate; the Vin+ electrical connector is disposed adjacent to four corners of the area where the BGA unit is disposed; each of the Vin+ electrical connectors is adjacent to a GND electrical connector;
wherein the voltage regulating device further comprising a Vin+ unit, the Vin+ unit is disposed on the lower surface of the second circuit substrate, and a projection of each of the Vin+ electrical connectors on the lower surface of the second circuit substrate at least partially overlaps the Vin+ unit.

Preferably, the voltage regulating device comprises three left-side voltage regulating units and three right-side voltage regulating units, the three left-side voltage regulating units are arranged adjacent to each other, and the three right-side voltage regulating units are arranged adjacent to each other.

Preferably, the seven bridge arm units adopt the same layout structure.

A voltage regulating device, comprising:
a bridge arm unit and an inductor assembly, wherein the bridge arm unit and the inductor assembly are electrically connected and stacked in a vertical direction;
wherein the bridge arm unit includes a first switch bridge arm, a second switch bridge arm, a third switch bridge arm, and a fourth switch bridge arm, each of the switch bridge arms includes a pin SW;
wherein the inductor assembly comprises a magnetic core and a winding; a vertical projection plane of the magnetic core is on the horizontal plane where the bridge arm unit is located, and each pin SW is arranged along the outer sides of the vertical projection plane.

Preferably, further comprising a BGA unit electrically connected to the inductor assembly, the bridge arm unit, the inductor assembly, and the BGA unit are stacked in a vertical direction.

Preferably, further comprising a first circuit substrate and a second circuit substrate, wherein the first circuit substrate and the second circuit substrate both comprise an upper surface and a lower surface opposite to each other; the bridge arm unit is disposed on the upper surface of the first circuit substrate, the inductor assembly is disposed between the first circuit substrate and the upper surface of the second circuit substrate, and the bridge arm unit and the inductor assembly are electrically connected through the first circuit substrate; the BGA unit is disposed on the lower surface of the second circuit substrate, and the inductor assembly and the BGA unit are electrically connected through the second circuit substrate;
wherein the voltage regulating device further comprising a Vin+ electrical connector, a GND electrical connector, and a Sig electrical connector; the Vin+ electrical connector, the GND electrical connector and the Sig electrical connector are disposed between the first circuit substrate and the second circuit substrate and are used for transferring power and signals between the first circuit substrate and the second circuit substrate; the Vin+ electrical connector is disposed adjacent to four corners of the area where the BGA unit is disposed; each of the Vin+ electrical connectors is adjacent to a GND electrical connector;
wherein the voltage regulating device further comprising a Vin+ unit, the Vin+ unit is disposed on the lower surface of the second circuit substrate, and a projection of each of the Vin+ electrical connectors on the lower surface of the second circuit substrate at least partially overlaps the Vin+ unit.

Preferably, each switch bridge arm comprises a pin Sig, the pins Sig and the pin SW are arranged on the two opposite sides of each switch bridge arm; the pins Sig of the first switch bridge arm and the third switch bridge arm are arranged adjacent to each other, and both are in the vertical projection plane; the pins Sig of the second switch bridge arm and the third switch bridge arm are both arranged outside the vertical projection plane.

Compared with the prior art, the application has the following beneficial effects:

(1) The present application provides a voltage regulating circuit, the voltage regulating circuit comprising an N-phase buck circuit and an additional branch that are electrically connected in parallel, wherein N is a natural number greater than 1, and the N output inductors are coupled or not coupled; the additional branch comprises N−1 additional inductors coupled to the N−1 inductors and connected in series sequentially and connected in series with one series inductor, thereby improving the response speed to the load jump.

(2) The present application provides a unit inductor, combining a circuit substrate and an inductor magnetic core, the unit inductor comprises a power network required by the unit inductor, and other power networks and control signals can also be integrated; and the number of required unit inductors can be selected according to the total power that needs to be processed by the voltage regulating device or the different numbers of load that need to be supplied, thereby simplifying the design, and improving the consistency and reliability of each unit of the circuit.

(3) The present application provides a voltage regulating device. A top surface of the inductor assembly is exposed to the first circuit substrate, so that the inductor magnetic core contacts a heat dissipation cold plate above the module, thereby improving thermal performance thereof; and a structure and a connection between the inductor assembly and the first circuit substrate and the second circuit member are provided to further reduce the height of the voltage regulating device.

### BRIEF DESCRIPTION OF THE DRAWINGS

FIG. 1A and FIG. 1B are voltage regulating circuits.

FIG. 2A to FIG. 2F are structures of an inductor assembly.

FIG. 2G and FIG. 2H are structures of another inductor magnetic core.

FIG. 3A and FIG. 3B are structures of another inductor assembly.

FIG. 4A to FIG. 4C are schematic structural diagrams and exploded schematic diagrams of a voltage regulating device.

FIG. 5A to FIG. 5E are schematic structural diagrams of another voltage regulating device.

FIG. 6A and FIG. 6B are structures of another inductor assembly.

FIG. 7A to FIG. 7G are another inductor assembly and winding structure and a manufacturing process.

### DESCRIPTION OF THE EMBODIMENTS

One of the cores of the present application is to provide a solution for high efficiency, high dynamic performance, high reliability, and low cost of the voltage regulating device.

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

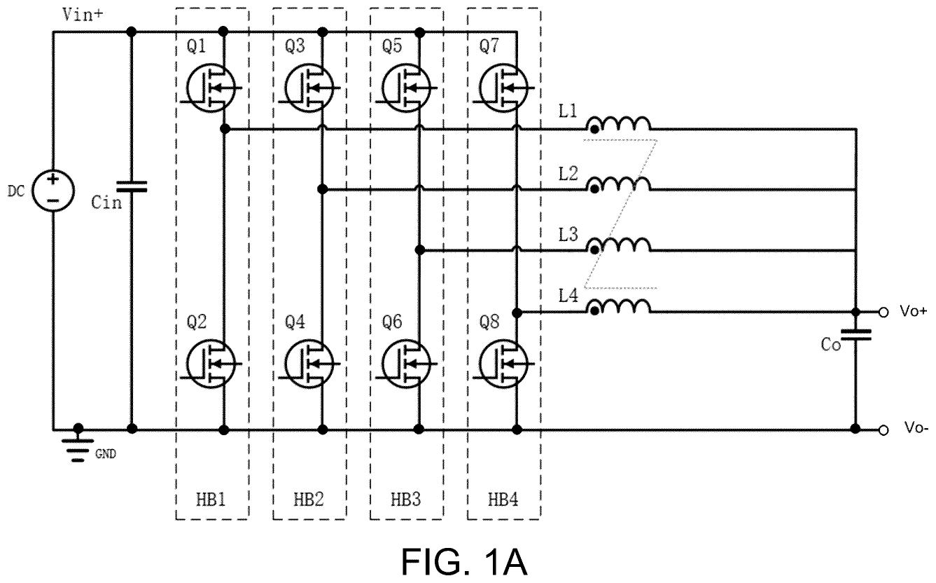

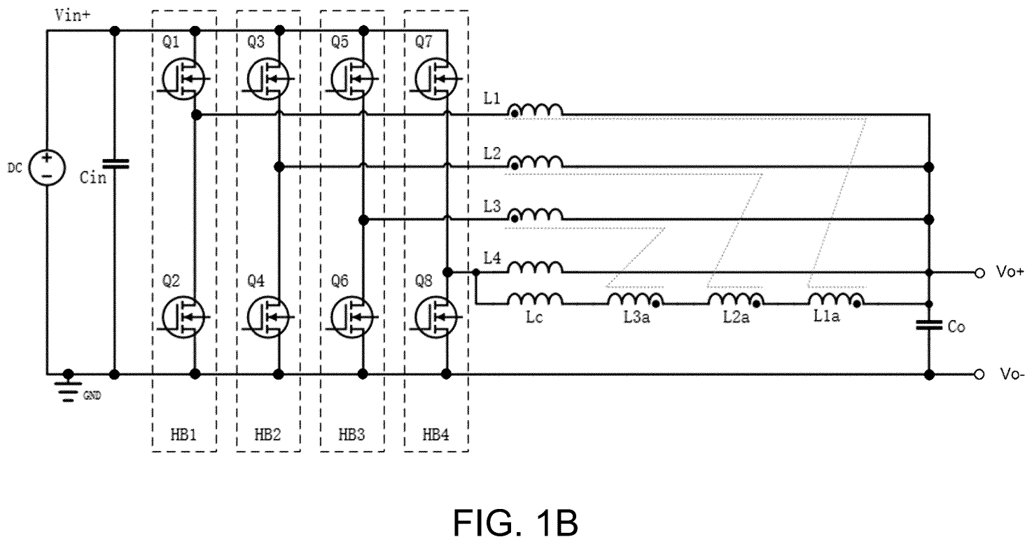

The voltage regulating circuit disclosed in the present application is shown in FIG. 1A and FIG. 1B. FIG. 1A is a voltage regulating circuit with an output inductor coupled, hereinafter briefly referred to as a circuit Ckt1. FIG. 1B is a voltage regulating circuit for adding an additional branch, hereinafter briefly referred to as a circuit Ckt2. The circuit Ckt1 includes N-phase buck circuit (N is a natural number greater than 1) connected in parallel, and the N-phase buck circuit is sequentially staggered by 360 degrees/N in phase. Each phase buck circuit includes a switch bridge arm and an output inductor, a first end of the output inductor is electrically connected to a midpoint SW of the switch bridge arm, and a second end of the output inductor is electrically connected to an output positive terminal Vo+, and the N phase output inductors are coupled. The switch bridge arm is connected between the input positive terminal Vin+ and the input negative terminal Vin−. In the present embodiment, the input negative terminal Vin− and the output negative terminal Vo− are short-circuited (i.e., the ground terminal GND). In detail, as an example in the 4-phase buck circuit shown in FIG. 1A, the 4-phase buck circuit includes four switch bridge arms HB1/HB2/HB3/HB4 and four output inductors L1/L2/L3/L4. A first end of each output inductor is electrically connected to a midpoint SW of one corresponding switch bridge arm, and a second end of the four output inductors L1/L2/L3/L4 are electrically connected to the output positive terminal Vo+; the coupling coefficient k of the four output inductors L1/L2/L3/L4 is in the range (−1, 1), that is, −1<k<1; the first ends of the four output inductors L1/L2/L3/L4 have the same polarity and are marked as point end. Four switch bridge arms are connected in parallel between the input positive terminal Vin+ and the ground terminal GND. The two-phase, three-phase, or more than four-phase buck circuits can be correspondingly modified according to the 4-phase buck circuit.

The circuit Ckt2 comprises N-phase buck circuit (N is a natural number greater than 1) connected in parallel, and the N-phase buck circuit is sequentially staggered by 360 degrees/N in phase. Each phase buck circuit includes a switch bridge arm and an output inductor, a first end of the output inductor is electrically connected to a midpoint SW of the switch bridge arm, a second end of the output inductor is electrically connected to the output positive terminal Vo+, and the N-phase output inductor may be coupled to each other, or may be N discrete inductors. The switch bridge arm is connected between the input positive terminal Vin+ and the input negative terminal Vin−. In the present embodiment, the input negative terminal Vin− and the output negative terminal Vo− are short-circuited (i.e., the ground terminal GND). The circuit Ckt2 further comprises N−1 additional windings and a series inductor, the N−1 additional windings are respectively coupled to the 1st to (N−1)th output inductors, and the N−1 additional windings and one series inductor are sequentially connected in series, and then are electrically connected in parallel with the Nth output inductor. In detail, as an example in the 4-phase buck circuit shown in FIG. 1B, the 4-phase buck circuit includes four switch bridge arms HB1/HB2/HB3/HB4, four output inductors L1/L2/L3/L4 and one additional branch, and the additional branch includes three additional windings L1a/L2a/L3a and a series inductor Lc. A first end of each output inductor is electrically connected to a midpoint SW of a corresponding switch bridge arm, and a second end of the four output inductors L1/L2/L3/L4 are electrically connected to an output positive terminal Vo+; and the four output inductors L1/L2/L3/L4 are not coupled to each other. Four switch bridge arms are connected in parallel between the input positive terminal Vin+ and the ground terminal GND. The additional winding L1a is coupled to the output inductor L1, and the coupling coefficient is k1; and the first end of the additional winding L1a and the first end of the output inductor L1 have the same polarity and are marked as point ends. The additional winding L2a is coupled to the output inductor L2, and the coupling coefficient is k2; and the first end of the additional winding L2a and the first end of the output inductor L2 have the same polarity and are marked as point ends. The additional winding L3a is coupled to the output inductor L3, and the coupling coefficient is k3; and the first end of the additional winding L3a and the first end of the output inductor L3 have the same polarity and are marked as point ends. In the additional branch, the second end of the additional winding L1a is electrically connected to the first end of the additional winding L2a, the second end of the additional winding L2a is electrically connected to the first end of the additional winding L3a, and then connected in series with the series inductor Lc; the additional branch is connected in parallel to the two ends of the output inductor L4. The coupling coefficients k1, k2, and k3 herein are all greater than 0.5. The series inductor Lc may be an independent inductor, or may be a leakage inductance or a parasitic inductance on a circuit between the additional winding Lna and the output inductor Ln, or any two or all of the above three. The addition of the additional branch can effectively reduce the transient output inductance of the voltage regulating circuit and improve the load transient response capability. The additional branch can also be applied to the coupling inductor shown in FIG. 1A, and also has the same technical effect. In addition, according to different power requirements, the two-phase, three-phase, or more than 4-phase buck circuits may be added according to the 4-phase circuit Ckt2 shown in FIG. 1B, and corresponding additional branches may also be added, which may also have the same technical effect.

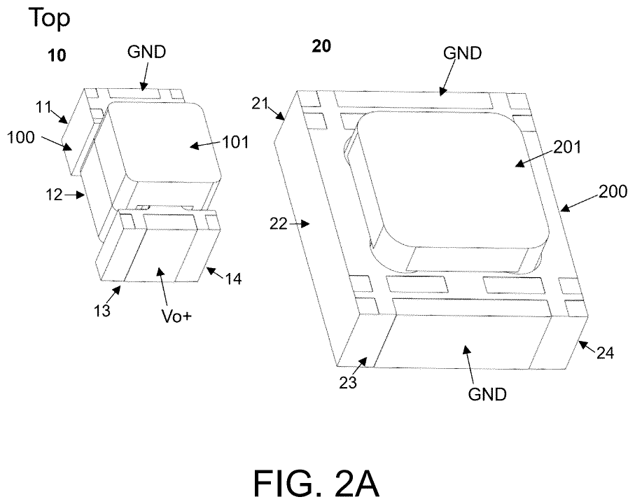

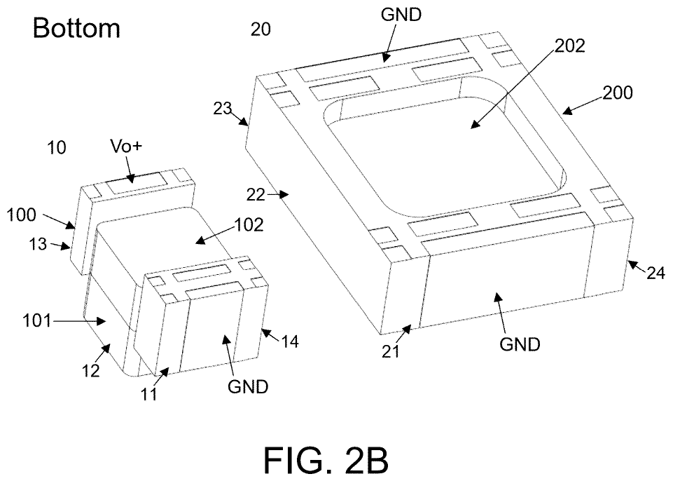

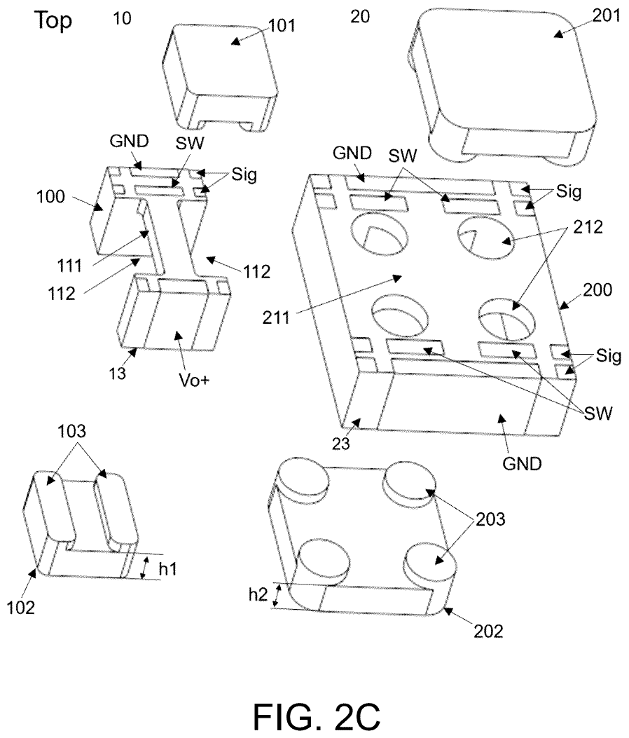

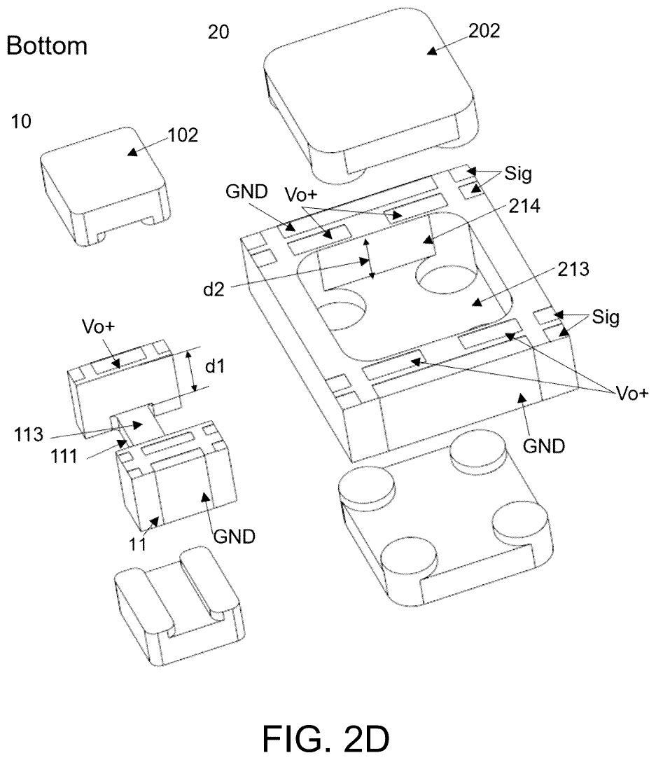

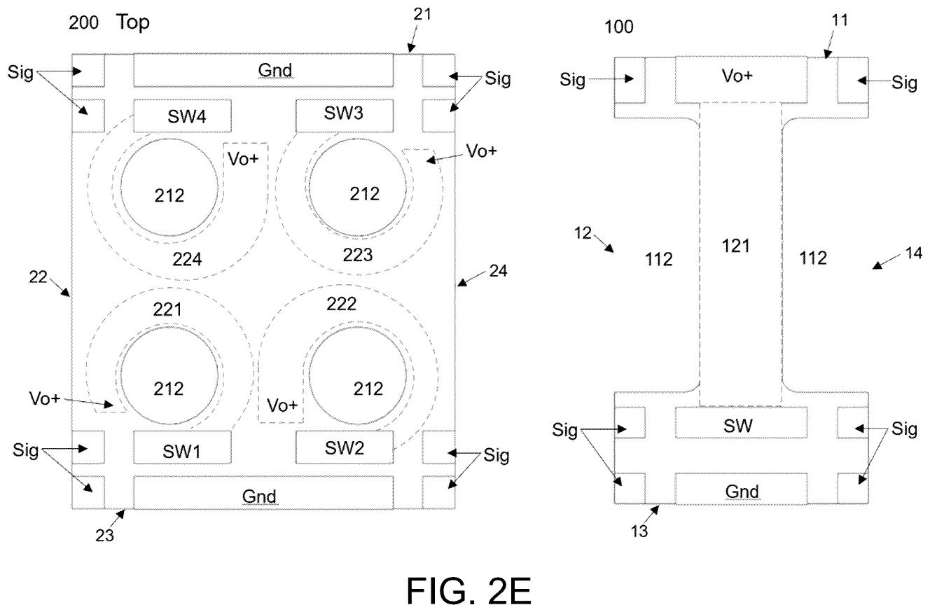

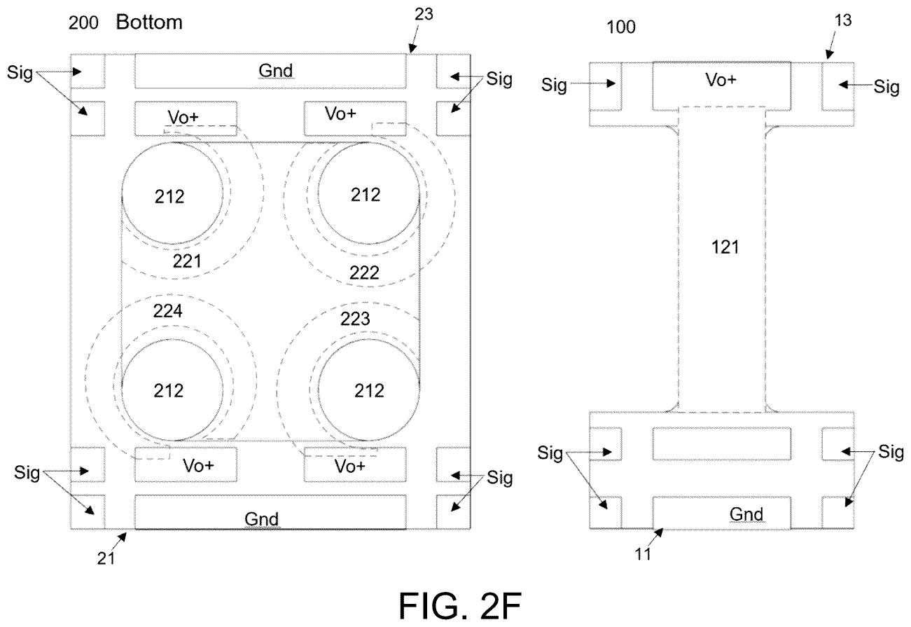

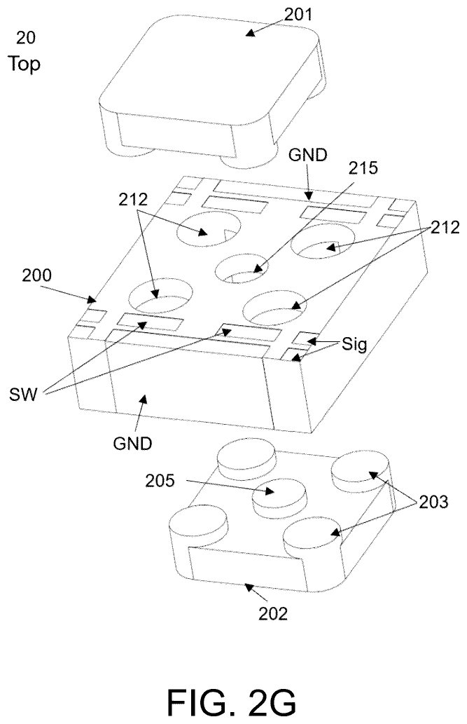

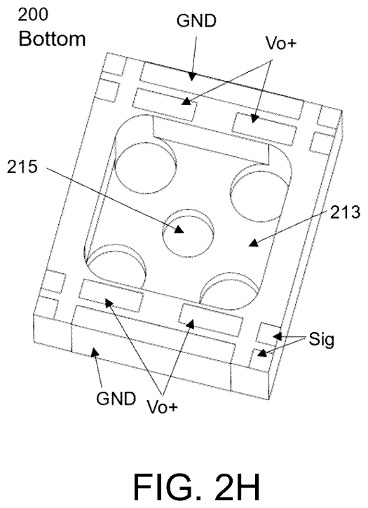

FIG. 2A to FIG. 2F show the inductor assemblies 10 and 20 required by the circuits Ckt1 and Ckt2, where FIG. 2A and FIG. 2B are respectively a top surface schematic diagram and a bottom surface schematic diagram of the inductor assembly 10/20, and FIG. 2C and FIG. 2D are respectively a top surface decomposition schematic diagram and a bottom surface decomposition schematic diagram of the inductor assembly 10/20, and FIG. 2E and FIG. 2F are respectively a top surface perspective schematic diagram and a bottom surface perspective schematic diagram of the inductor assembly 10/20.

The inductor assembly 10 is a single-phase output inductor coupled with an additional winding, comprising a single-phase inductor magnetic core and a single-phase inductor frame 100. In combination with FIGS. 2A to 2F, the single-phase inductor magnetic core comprises an upper magnetic cover 101, a lower magnetic cover 102, and two inductor magnetic columns 103, wherein the two inductor magnetic columns 103 are both arranged between the upper magnetic cover 101 and the lower magnetic cover 102, and one winding column channel exists between the two single-phase inductor magnetic columns.

The single-phase inductor frame 100 (i.e., inductor assembly 10) comprising a first side 11 and a third side 13 opposite to each other and a second side 12 and a fourth side 14 opposite to each other. A winding frame 111 is arranged in a direction extending from the first side 11 to the third side 13 and adjacent to the top surface of the inductor assembly 10. The inductor winding L1 and the additional winding L1a are arranged in the winding frame 111, and the inductor winding L1 or the additional winding L1a can be implemented by an internal wiring of the winding frame; the inductor winding L1 and the additional winding L1a can also be a metal strip embedded in the winding frame, and the copper strip is optimal; and the inductor winding L1 and the additional winding L1a can also be implemented by electroplating on the surface of the winding frame 111. The inductor assembly 10 further comprises two through grooves 112 recessed inwardly from the second side 12 and the fourth side 14 to the winding frame 111 respectively, the through grooves 112 penetrate the top and bottom surfaces of the inductor assembly. The inductor assembly 10 further comprises a blind groove 113 recessed inwardly from the bottom of the inductor assembly 10 to the winding frame, the depth of the blind groove 113 is d1.

The electrical connector GND is provided on the outer side wall of the first side 11 of the inductor assembly 10, and can be implemented by means of punching or side edge plating, and respectively form a GND end portion on the top surface and the bottom surface of the inductor assembly 10 for being soldered and fixed and electrically connected to the other components. The electrical connector Vo+ is disposed on the outer side wall of the third side 13 of the inductor assembly, and can also be implemented by means of punching or side-edge plating, and forms a Vo+ end portion on the top surface and the bottom surface of the inductor assembly 10 respectively, and the electrical connector Vo+ is electrically connected to the second end of the inductor winding in the single-phase inductor frame 100. The electrical connector SW is disposed adjacent to the electrical connector GND and is electrically connected to the first end of the inductor winding disposed within the winding frame 111, the electrical connector SW forming a SW end portion on the top surface of the inductor assembly 10, the SW end portion being connected to the midpoint of the bridge arm by welding. The single-phase inductor frame 100 further comprises a plurality of electrical connectors Sig, arranged adjacent to the first side 11 and the third side 13 of the inductor assembly 10 respectively, and the positions thereof are not specifically limited. The first end and the second end of the additional winding are electrically connected to an electrical connector Sig on the first side 11 and the third side 13 respectively, and the two electrical connectors Sig are used for connecting the additional branches. In addition, other electrical connections Sig may be used to transmit PWM control signals, current detection, temperature detection, and auxiliary power supply. The electrical connectors SW, Sig, and Vo+ can all be implemented by punching, side plating, or embedded copper blocks; in addition, other power networks such as Vin+ can also be integrated in the inductor assembly.

The single-phase inductor frame 100 may be a printed circuit board, but is not limited thereto, and may also be other types of circuit substrates. The single-phase inductor magnetic core is buckled with the winding frame 111 from the top surface and the bottom surface respectively, and the two inductor magnetic columns respectively pass through the two through grooves 112, so that the winding frame 111 is accommodated in the winding column channel. The thickness of the lower magnetic cover of the single-phase inductor magnetic core is h1, and the design here is such that the blind groove depth d1>h1, so that the surface of the lower magnetic cover of the inductor assembly 10 after assembly is recessed within the bottom surface of the inductor frame 100, so that each end portion disposed on the bottom surface of the inductor frame 100 may be directly welded and fixed to the other components and electrically connected.

Referring also to FIG. 2A to FIG. 2F, the inductor assembly 20 is a four-phase output inductor, and the four-phase inductor magnetic core includes an upper magnetic cover 201, a lower magnetic cover 202, and four inductor magnetic columns 203. The four inductor magnetic columns 203 are all disposed between the upper magnetic cover 201 and the lower magnetic cover 202, and the four inductor magnetic columns form a square.

The four-phase inductor frame 200 (i.e., the inductor assembly 20) comprises opposing first and third sides 21, 23 and opposing second and fourth sides 22, 24. A winding frames 211 comprising four through grooves 212, the four through grooves penetrate through the top and bottom surfaces of the inductor assembly 20 supplying the four inductor magnetic columns 203 to pass through respectively. The winding frame 211 is disposed adjacent to the top surface of the inductor assembly 20. The inductor windings L1/L2/L3/L4 are arranged in the winding frame 211, and the inductor windings L1/L2/L3/L4 are wound around one through groove 212 respectively; the inductor windings L1/L2/L3/L4 can be implemented by means of the internal wiring of the circuit substrate, and can be metal strips embedded in the circuit substrate wherein copper strips are optimal, and can also be realized by electroplating on the surface of the winding frame 111. The inductor assembly 20 further comprises a blind groove 213 recessed from the bottom surface of the inductor assembly 20 to the winding frame 211 for accommodating the lower magnetic cover 202 of the four-phase inductor magnetic core; the depth of the blind groove 213 is d2.

The electrical connector GND is provided on the outer side wall of the first side 21 and the outer side wall of the third side 23 of the inductor assembly 20, can be realized by means of punching or side-edge plating, and forms a GND end portion at the top surface and the bottom surface of the inductor assembly 20 respectively for being soldered and fixed and electrically connected to the other components. Four electrical connectors Vo+ are disposed adjacent to the first side 21 and third side 23 of the inductor assembly 20, and four Vo+ end portions are formed on the bottom surface of the inductor assembly 20 respectively, each electrical connector Vo+ being electrically connected within the four-phase inductor frame 200 with the second end of one inductor winding. Four electrical connectors SW are disposed adjacent to the first side 21 and third side 23 of the inductor assembly 20 and form four SW end portions respectively on the top surface of the inductor assembly 20, each electrical connector SW being electrically connected within the four-phase inductor frame 200 with the first end of one inductor winding; each SW end portion is connected to the midpoint of the bridge arm of one switch bridge arm by welding. The four-phase inductor frame 200 further comprises a plurality of electrical connectors Sig, disposed adjacent to the first side 21 and/or the third side 23 of the inductor assembly 20, and the positions thereof are not specifically limited. The electrical connector Sig can be used for transmitting PWM control signals, current detection, temperature detection, auxiliary power supply, and the like. The electrical connectors SW, Sig, and Vo+ can all be implemented by punching, side plating, or embedded copper blocks; in addition, other power networks such as Vin+ can also be integrated in the inductor assembly. Optionally, in the inductor assembly 20, three additional windings L1a/L2a/L3a may also be provided, and the three additional windings L1a/L2a/L3a are respectively wound according to the path of the inductor winding L1/L2/L3, and the first end and the second end of each additional winding may be electrically connected to one Sig end portion respectively, or may be electrically connected inside the inductor assembly 20 and only electrically connected with two Sig end portions for the connection of additional branches.

The four-phase inductor frame 200 may be a printed circuit board, but is not limited thereto, and may also be other types of circuit substrates. The four-phase inductor magnetic cores are respectively buckled with the winding frame 211 from the top surface and the bottom surface, and the four inductor magnetic columns respectively passing through the four through grooves 212. The thickness of the lower magnetic cover of the four-phase inductor magnetic core is h2. Here, the depth d2 of the blind groove is designed to be greater than or equal to h2, so that the surface of the lower magnetic cover of the assembled inductor assembly 20 is recessed within or flush with the bottom surface of the inductor frame 200, so that each end portion provided on the bottom surface of the inductor frame 200 can be directly welded and fixed to the other components and electrically connected.

In order to further improve the inductance of the inductor assembly, an inductor middle column 205 can be added on the basis of the four-phase inductor magnetic core shown in FIG. 2A to FIG. 2F, as shown in FIG. 2G and FIG. 2H. FIG. 2G is a top exploded view of the inductor assembly 20, and FIG. 2H is a schematic diagram of a bottom surface of the inductor frame 200. Referring to FIG. 2G and FIG. 2H, the inductor middle column 205 is arranged between the four magnetic columns 203; correspondingly, the inductor frame 200 further comprises a middle column through groove 215, and the inductor middle column 205 passes through the through groove 215. The winding manner of the inductor winding, the arrangement of the electrical connector and the end portion, and the connection manner with other components are the same as those in the embodiment shown in FIG. 2A to FIG. 2F, and details are not described herein again. Still further, the inductive saturation may be prevented by disposing an air gap on the inductor middle column 205, or selecting a magnetically permeable material having a low magnetic permeability. The method for increasing a middle column is not limited to a four-phase inductor magnetic core, and other multiphase inductors can improve inductance by increasing an inductor middle column.

Here, the inductor assembly 20 is only described by taking a four-phase coupling inductor as an example, and the structure is also applicable to a two-phase coupling inductor, a three-phase coupling inductor, or a coupling inductor greater than four phases. The number and arrangement of the inductor magnetic columns, the number of through grooves, and the arrangement thereof can be changed accordingly, which will not be repeated here in the present application.

In this application, the inductor core material may be ferrite or iron powder, or a mixture of two. Conventional coupled inductor core materials often use a single ferrite, in this case, in order to prevent the saturation of the inductor, the air gap needs to be increased in the magnetic circuit to reduce the magnetic reluctance, but the air gap will cut the surrounding conductor to generate eddy current loss; or when the inductor magnetic core material uses a single iron powder, due to the low magnetic permeability of the iron powder, the inductance is too low. Therefore, in the present application, one of the two magnetic covers of the inductor magnetic core material can be a high magnetic permeability material, such as ferrite, and the other of the two magnetic covers can be a low magnetic permeability material, such as an iron powder; here, the ratio of the high magnetic permeability to the low magnetic permeability is greater than 5. The characteristics of the two magnetic materials of ferrite and iron powder can be used at the same time, so that a large inductance can be obtained, eddy current loss caused by air gaps can be avoided, and the manufacturing is easy to manufacture.

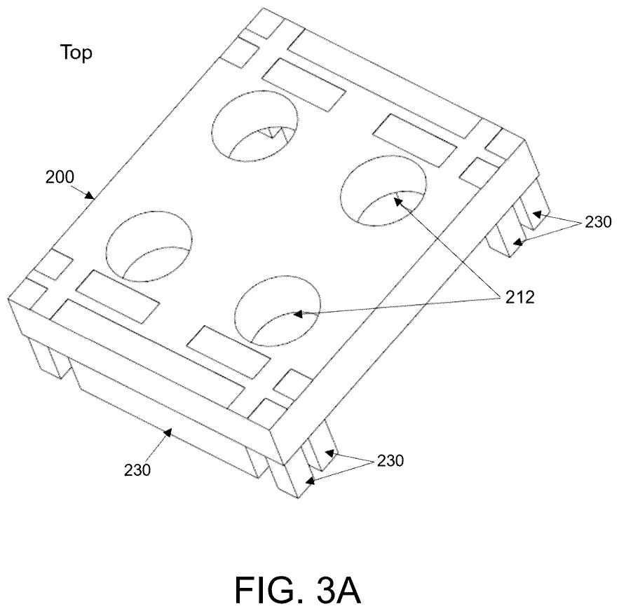

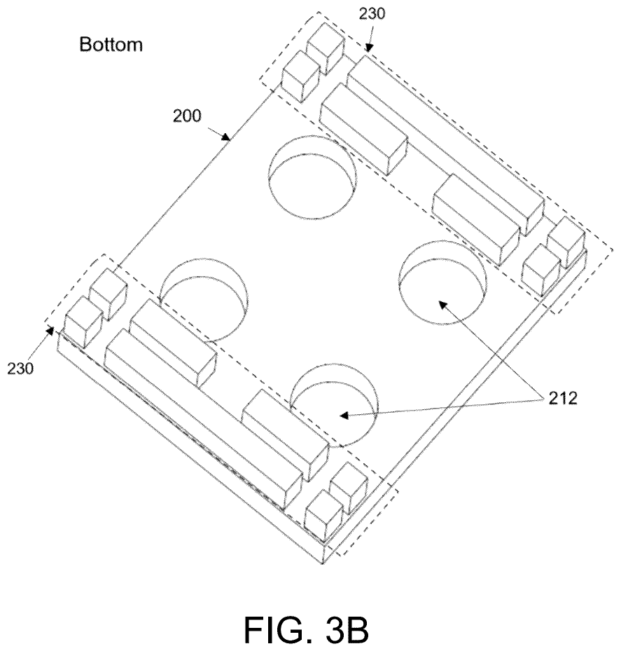

Optionally, the inductor frame may not include a blind groove, that is, a bottom surface of the winding frame and a bottom surface of the inductor frame are coplanar, as shown in FIG. 3A and FIG. 3B. By welding the independent electrical connectors 230 on the bottom surface, the independent electrical connectors herein may be metal blocks or other electrical connectors, the bottom or bottom end portions of these independent electrical connectors being the desired Vo+ end portion, GND end portion or Sig end portion for being secured and electrically connected with other components. Here, the metal block is optimal by using copper blocks, but is not limited thereto, as long as the metal has good conductivity.

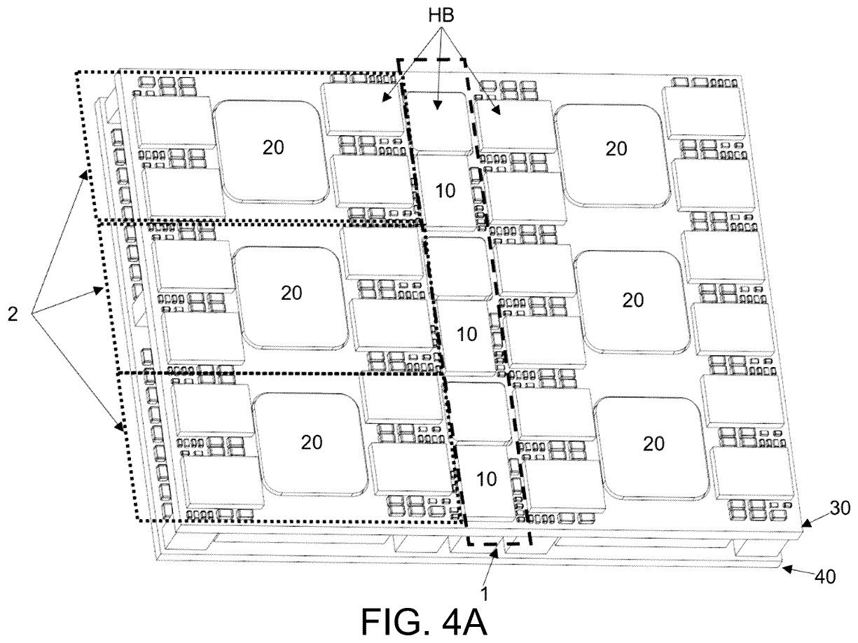

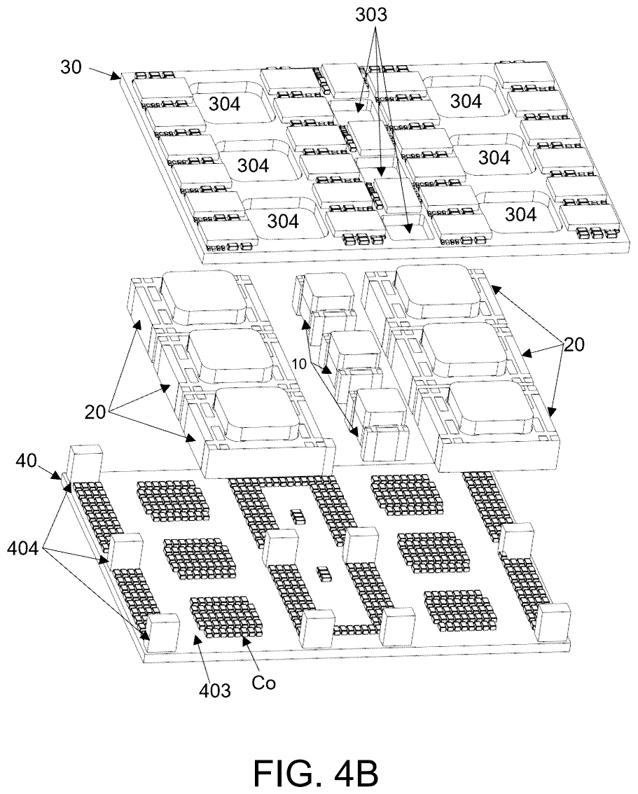

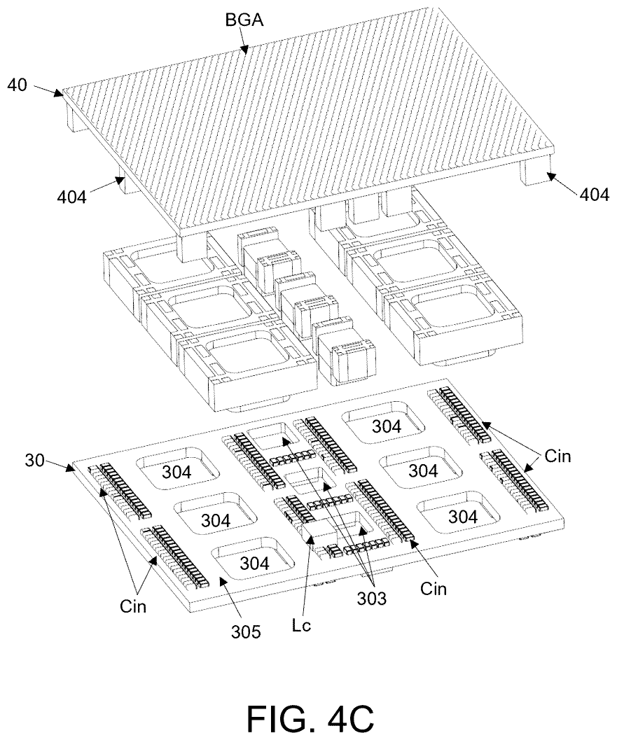

The present application further discloses a structure of a voltage regulating device, as shown in FIG. 4A to FIG. 4C. FIG. 4A is a top view of the voltage regulating device, FIG. 4B is a top exploded view of the voltage regulating device, and FIG. 4C is a schematic exploded view of a bottom surface of the voltage regulating device.

As shown in FIGS. 4A to 4C, the voltage regulating device comprises six modules 2 and one module 1, each module sharing a first circuit substrate 30 and a second circuit substrate 40. In this application, the module 2 adopts a four-phase buck circuit; the module 1 comprises three one-phase buck module and the one-phase buck module adopts one-phase buck circuit; In the other application, the phase number of every module is not limited thereto. The first circuit substrate 30 comprising an upper surface 301 and a lower surface 302 opposite to each other, a single-phase through groove 303 and a four-phase through groove 304, the through grooves 303 and 304 both penetrating the upper surface 301 and the lower surface 302. The switch bridge arms HB are arranged on the upper surface 301, and the input capacitors Cin are arranged on the upper surface 301 and the lower surface 302; in detail, four switch bridge arms HB are disposed around a four-phase through groove 302. In the present embodiment, two switch bridge arms HB are arranged adjacent to one side of the four-phase through groove 302, and the other two switch bridge arms HB are arranged on the other side of the four-phase through groove 302, but not limited thereto, and it is necessary to determine according to the actual number of phases and the winding manner of the inductor winding, as long as the bridge arm midpoint SW of the switch bridge arm HB is arranged adjacent to the first end of the inductor winding. The input capacitor Cin is disposed adjacent to the input end of the switch bridge arm HB. Each single-phase through groove 301 is adjacent to one switch bridge arm HB, and the three single-phase through grooves and the three switch bridge arms may be arranged in one column as shown in FIG. 4A, or may be horizontally arranged in one row; or the three single-phase through grooves are arranged in one row or one column, and the three switch bridge arms are arranged in another row or another column, and are not limited thereto. As long as the bridge arm midpoint SW of the switch bridge arm is disposed adjacent to the first end of the inductor winding. The plurality of input capacitors Cin and the series inductor Lc are disposed on the lower surface 302 of the first circuit substrate 30, the input capacitor Cin is disposed adjacent to an input end of the switch bridge arm HB, and the Lc is disposed adjacent to the module 1. The lower surface 302 further comprises a pad region 305 for soldering and fixing and electrically connecting the inductor assemblies 10 and 20. In this embodiment, the switch bridge arm and the first terminal of the inductor winding are connected nearby, which can effectively reduce the parasitic impedance on the power transmission path, reduce the transmission loss, and improve the conversion efficiency of the module.

The upper magnetic cover 101 of the inductor assembly 10 passes through the single-phase through groove 303, and the upper surface of the upper magnetic cover 101 is exposed to the top surface of the voltage regulating device; the end portion of the top surface of the inductor assembly 10 is in contact with the lower surface 302, and the end portion is fixedly and electrically connected to a corresponding pad provided in the pad region 305. In this embodiment, the upper surface of the upper magnetic cover 101 is exposed, so that the heat generated by the inductor assembly can be effectively dissipated, and the temperature of the inductor assembly can be reduced; furthermore, the inductor magnetic core can be in contact with the heat dissipation cold plate above the module, thereby further improving the thermal performance of the inductor assembly.

The second circuit substrate comprises an upper surface 401 and a lower surface 402, the upper surface 401 comprising a pad region 403, a plurality of pads are disposed on the pad region 403 and is used for welding and fixing and electrically connecting to the end of the bottom surface of the inductor assembly or the bottom surface of the independent electrical connector or the bottom end of the independent electrical connector. A plurality of independent electrical connectors 404 are provided on the upper surface 401 for transmitting input power, a control signal or a sampling signal. The independent electrical connectors 404 include electrical connectors Vin+, and the electrical connectors Vin+ may be disposed adjacent to the switch bridge arms, and each switch bridge arm may be matched with one electrical connector Vin+, or two or more switch bridge arms may share one electrical connector Vin+. The independent electrical connectors 404 may also be electrical connectors GND, or electrical connectors Sig. The first end of the independent electrical connector 404 is fixed and electrically connected to the lower surface 302 of the first circuit substrate, and the second end thereof is fixed and electrically connected to the upper surface 401 of the second circuit substrate, so that the power transmission or signal transmission between the first circuit substrate 30 and the second circuit substrate 40 can be achieved, and a certain mechanical support effect is provided between the first circuit substrate and the second circuit substrate.

The lower surface 402 of the second circuit substrate 40 is provided with a BGA array. The BGA array can be an output positive terminal Vo+, a ground terminal GND, an input positive terminal Vin+ or other signal terminals. The layout of the BGA array can be flexibly set according to the requirements of the customer. The solder pads of the BGA array and the upper surface 401 are electrically connected respectively through wiring within the circuit substrate.

In this embodiment, the switch bridge arm and the inductor assembly are arranged horizontally, that is, the projections of the switch bridge arm and the magnetic core of the inductor assembly have no overlapping area in the vertical direction, and therefore, the utilization rate of the inductor magnetic core in the height direction of the module reaches the maximum. The upper magnetic cover surface of the inductor magnetic core is exposed from the top surface of the module through the through groove, the lower magnetic cover is disposed in the blind groove of the inductor frame, and the output capacitor combination is arranged at the position corresponding to the blind groove on the upper surface 401 of the second circuit substrate, so that the dynamic response capability of the module can be further improved; and the height of the module is further reduced, which is more suitable for applications with high requirements for the height of the module.

In the voltage regulating device shown in FIG. 4A to FIG. 4C, the output terminals of the six modules 2 are independently output, and the output terminals of the one-phase module in module 1 are electrically connected in parallel; in other embodiments, the output terminals of the modules are parallel or independent depending on whether the loads thereof are parallel or independent. In another embodiment, the voltage regulating device may also include only one module. In summary, the specific design can be specifically designed according to the power size of the actual load and whether it is independent or not.

The present application provides another voltage regulating device, which also adopts a multi-phase buck circuit in parallel for the application of multiple outputs. By optimizing the structure of the inductor component, the structural layout of the voltage regulating device is optimized, the transient response performance of the output voltage is improved, the efficiency of the voltage regulating device is improved, and the size of the device is further reduced.

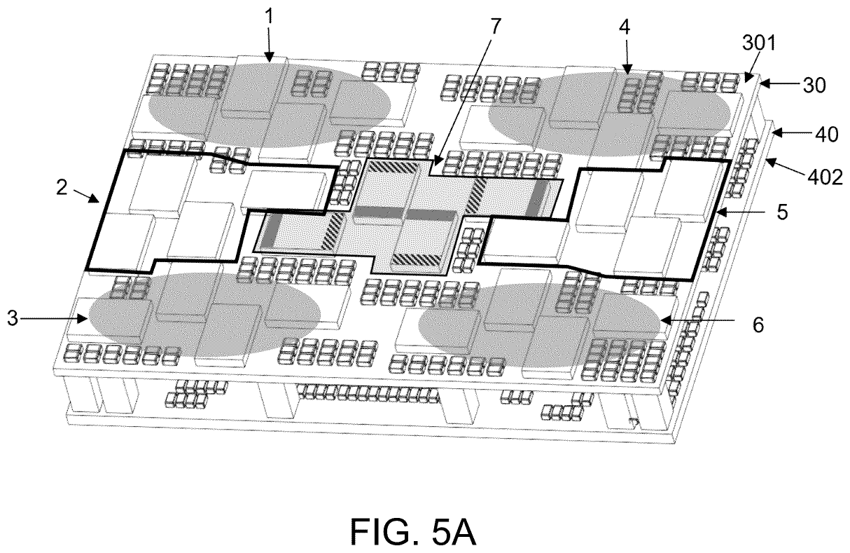

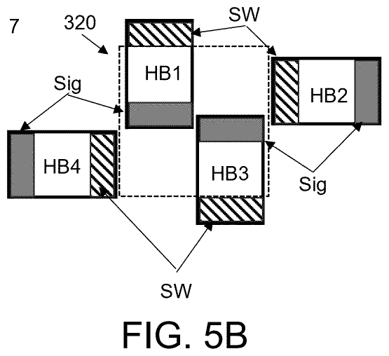

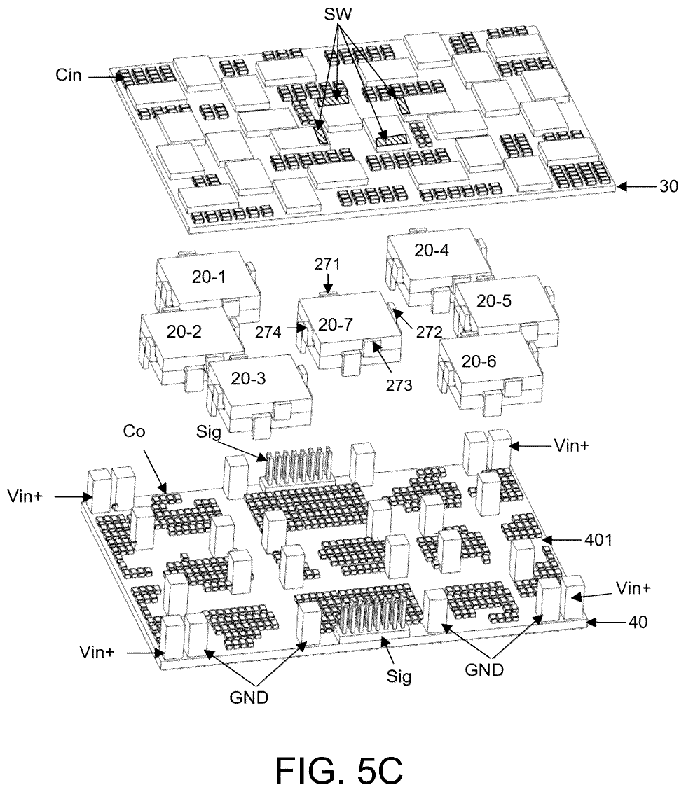

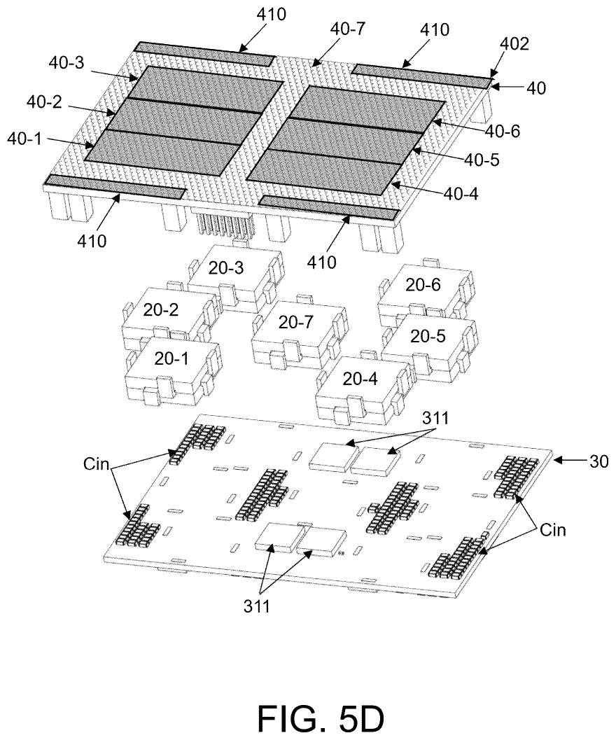

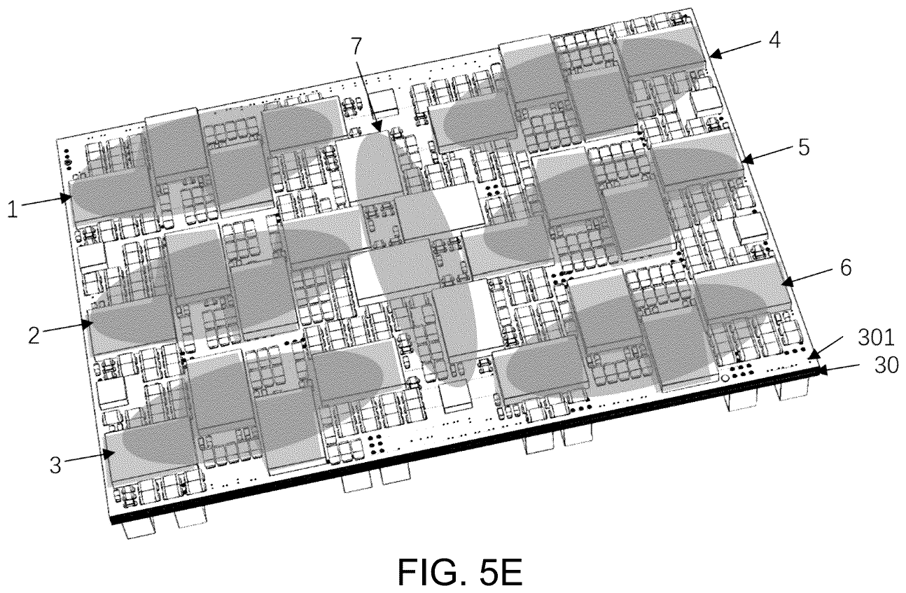

FIG. 5A is a schematic perspective view of a voltage adjustment apparatus, and FIG. 5B is a partial schematic diagram. As shown in FIG. 5A, the voltage regulating device comprises a first circuit substrate 30 and a second substrate 40; the first circuit substrate 30 comprises an upper surface 301 and a lower surface 302 opposite to each other, the second circuit substrate 40 comprises an upper surface 401 and a lower surface 402 which are opposite to each other, and the plurality of switch bridge arms HB are arranged on the upper surface 301. The voltage regulating device comprises seven voltage regulating units, and each voltage regulating unit comprises a bridge arm unit and an inductor assembly; the connection modes of the bridge arm unit and the inductor assembly are referred to as shown in FIG. 1A in the same voltage regulating unit. Each bridge arm unit comprises four switch bridge arms HB1/HB2/HB3/HB4 in the circuit Ckt1 shown in FIG. 1A. On the upper surface 301 of the first circuit substrate 30, the bridge arm unit 7 is arranged at the middle position of the upper surface 301, the bridge arm units 1/2/3 are sequentially arranged on the left side of the bridge arm unit 7, the bridge arm units 4/5/6 are sequentially arranged on the right side of the bridge arm unit 7, that is, the bridge arm unit 7 is arranged among the bridge arm units 1 to 6. In the present embodiment, the outputs of the seven voltage regulating units may be independent; in other embodiments, the output terminals of some of the regulating units may also be electrically connected in parallel, for example, the output terminals of the first/second/third voltage regulating units are electrically connected in parallel, and the output terminals of the fourth/fifth/sixth voltage regulating units are electrically connected in parallel. In other embodiments, only the first voltage regulating unit, the fourth voltage regulating unit, and the seventh voltage regulating unit may be included, and the seventh voltage regulating unit is disposed between the first voltage regulating unit and the fourth voltage regulating unit. The voltage regulating device can include more than three voltage regulating units, and can be designed according to the layout principle described below.

The detail of the layout of the bridge arm unit can refer to FIG. 5B. Taking the bridge arm unit 7 as an example, the signal pin positions Sig of the switch bridge arms HB1 and HB3 are arranged adjacent to each other. Meanwhile, referring to FIG. 5C, the inductor assemblies 20-1 to 20-7 are arranged between the first circuit substrate 30 and the second circuit substrate 40, and each inductor assembly is arranged corresponding to one bridge arm unit. Taking the inductor assembly 20-7 as an example, the inductor assembly 20-7 corresponds to the bridge arm unit 7, the bridge arm unit 7 comprises four switch bridge arms HB1/HB2/HB3/HB4 in the circuit Ckt1, the inductor assembly 20-7 comprises four coupling inductors in the circuit Ckt1, and the connection mode thereof can be referred to as shown in FIG. 1A, the first end of each inductor is electrically connected to the pin SW of the switch bridge arm, and the second end of each inductor is electrically connected to the output positive terminal. The inductor assembly 20-7 comprises four inductor windings, a first end surface of the four inductor windings is 271/272/273/274 respectively, the four first end surfaces are disposed adjacent to the first circuit substrate 30, and a vertical projection of the inductor assembly 20-7 on the upper surface 301 is a projection region 320 (as shown in a dashed box region of FIG. 5B). In the present embodiment, the projection area 320 is square as an example for description. The switch pins SW of each switch bridge arm HB are respectively disposed adjacent to one side of the projection area 320, and signal pins Sig of the switch bridge arms HB1 and HB3 are adjacently arranged, signal pins Sig of the switch bridge arms HB1 and HB3 are disposed within the projection area 320, and signal pins Sig of the switch bridge arms HB2 and HB4 are disposed outside the projection area 320. In detail, the projections of the first end surface 271 and the switch pin SW of the switch bridge arm HB1 on the upper surface 301 are at least partially overlapped, the projections of the first end surface 272 and the switch pin SW of the switch bridge arm HB2 on the upper surface 301 are at least partially overlapped, the projections of the first end surface 273 and the switch pin SW of the switch bridge arm HB3 on the upper surface 301 are at least partially overlapped, and the projections of the first end surface 274 and the switch pin SW of the switch bridge arm HB4 on the upper surface 301 are at least partially overlapped. In this embodiment, the projections of the first end surface and the corresponding switch pin on the upper surface 301 is overlapped, so that the parasitic impedance of the switch bridge arm to the first end of the winding is minimized. As shown in FIG. 5A, the layout of the bridge arm units 1/3/4/6 are the same as the layout of the bridge arm unit 7; the layout of one of the bridge arm units 2/5 is slightly different, and the layout principle of the bridge arm units 2/5 also follow that the projections of the first end surface and the switch pin SW of the switch bridge arm on the upper surface 301 at least partially overlap.

At the same time, referring to FIGS. 5C and 5D, the lower surface 402 of the second circuit substrate 40 is provided with a BGA array, and the BGA array on the lower surface 402 comprises seven units, respectively BGA cells 40-1 to 40-7. BGA cells 40-1/40-2/40-3 are arranged adjacently in sequence, and the positions thereof are respectively arranged adjacent and corresponding to the inductor assemblies 20-1/20-2/20-3; the BGA units 40-4/40-5/40-6 are arranged adjacently in sequence, and the positions thereof are respectively arranged adjacent and corresponding to the inductor assemblies 20-4/20-5/20-6; and the BGA unit 40-7 is arranged around the BGA units 40-1/40-2/40-3 the BGA units 40-4/40-5/40-6. The circuit layout above enables the sum parasitic resistance (DCR) of the second end of the winding in the inductor assembly 20-7 to the Vo+ end portion in the BGA unit 40-7 to be minimum, so that the seventh voltage regulating unit has good dynamic response capability.

The BGA array further comprises a Vin+ unit 410 disposed adjacent to two opposite sides of the BGA cells 40-1/40-2/40-3, and disposed adjacent to two opposite sides of the BGA cells 40-4/40-5/40-6 respectively, and the Vint cells 410 are surrounded by the BGA cells 40-7. Correspondingly, referring to FIG. 5C, a Vin+ electrical connector, a GND electrical connector, and a Sig electrical connector are disposed on the upper surface 401 of the second circuit substrate 40, the electrical connectors are disposed between the first circuit substrate 30 and the second circuit substrate 40 and transmit power and signals between the first circuit substrate 30 and the second circuit substrate 40. The Vin+ electrical connectors are disposed adjacent to four corners of the BGA array, respectively, and each Vin+ electrical connector is disposed corresponding to one Vin+ unit 410, that is, the projection of each Vin+ electrical connector on the lower surface 402 of the second circuit substrate is at least partially overlapped with the Vin+ unit 410, thereby further reducing the parasitic impedance on the power input path and reducing the loss of the voltage regulating device. The Sig electrical connector is provided at a position between the BGA unit 40-1/40-2/40-3 and the BGA unit 40-4/40-5/40-6, facilitating the provision of a control signal and a transmission sampling signal for each bridge arm unit. In addition, each Vin+ electrical connector has a GND electrical connector adjacent to each other, so as to reduce parasitic inductance in the input loop; and other GND electrical connectors can be set according to actual requirements.

In addition, an input capacitor Cin is provided on the upper surface 301 and/or the lower surface 302 of the first circuit substrate 30, and the input capacitor Cin can be disposed between the switch bridge arms and can be disposed adjacent to the input pin of the switch bridge arm. An output capacitor Co may be disposed on the upper surface 401 of the second circuit substrate 40, and the output capacitor Co may be disposed below the inductor assembly, as shown in FIG. 5C. The second end of the inductor winding protrudes from the magnetic cover of the inductor assembly, so that after the inductor assembly is fixedly electrically connected to the second circuit substrate, a cavity is formed between the inductor assembly and the second circuit substrate for accommodating the output capacitor Co. In other embodiments, there may be no cavity between the inductor assembly and the second circuit substrate, and the output capacitor Co may be disposed adjacent to the second end of the inductor assembly.

FIG. 5E shows another layout mode of the upper surface 301 of the first circuit substrate 30, which differs from the layout mode shown in FIG. 5A in that the switch bridge arms in the seven bridge arm units adopt the same layout structure as shown in FIG. 5B; the bridge arm unit 7 is arranged at the middle position of the upper surface 301, the bridge arm units 1/2/3 are sequentially arranged on the left side of the bridge arm unit 7, the bridge arm units 4/5/6 are sequentially arranged on the right side of the bridge arm unit 7, that is, the bridge arm unit 7 is arranged among the bridge arm units 1 to 6. The arrangement direction of the bridge arm units 1 to 6 is the same as the arrangement direction of the bridge arm units 1 to 6 in FIG. 5B, and the arrangement direction of the bridge arm units 7 is rotated by 90 degrees compared to the arrangement direction of the bridge arm units 7 in FIG. 5B. In other words, the bridge arm units 1/2/3 and the bridge arm units 4/5/6 are symmetrically arranged along the bridge arm unit 7. Bridge arm units of the same layout structure can be used, so that the arrangement of seven bridge arm units is symmetrical and uniform, thereby improving the consistency of each bridge arm unit.

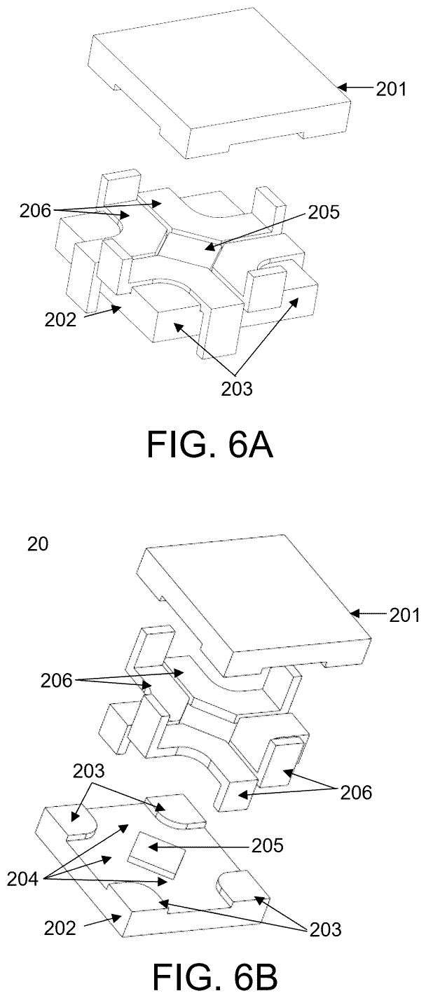

In order to improve the window utilization rate of the inductor assembly, the inductor assembly uses a five-column magnetic core and a metal winding method, as shown in FIG. 6A and FIG. 6B. The inductor assembly 20-1 to 20-7 comprises an upper magnetic cover 201, a lower magnetic cover 202, four winding columns 203, a middle column 205, and four metal windings 206. The middle column 205 is arranged between the four winding columns 203, the cavity between the winding column and the middle column being used for accommodating the metal winding 206. In the present embodiment, the metal winding 206 is implemented by using a copper sheet; in other embodiments, other metals having good conductive characteristics can also be used. Each inductor winding includes a horizontal winding section, an upward bent SW section, and a downward bent Vo+ section. The horizontal winding section is disposed between the winding column and the middle column, respectively, and the SW section and the Vo+ section of each winding are respectively disposed on two adjacent sides of the magnetic core. In a counterclockwise direction, the Vo+ section of each winding is disposed adjacent to the SW section of the next winding.

The upper magnetic cover and the lower magnetic cover of the magnetic core may use materials of different magnetic permeability, and the ratio of the high magnetic permeability to the low magnetic permeability is greater than or equal to 5 times; for example, the upper magnetic cover uses ferrite having high magnetic permeability, and the lower magnetic cover uses iron powder having low magnetic permeability. Such an advantage is to improve the anti-current saturation capability of the inductor assembly while satisfying the coupling coefficient of the inductor assembly. Furthermore, all the magnetic columns can be integrally formed with the upper magnetic cover, and ferrite is adopted; the middle column reluctance is adjusted by adjusting the size of the middle column air gap; in the limit, the air gap increases or even eliminates the existence of a middle column. In other embodiments, all the magnetic columns can be integrally formed with the lower magnetic cover, and iron powder is used; or the winding column and the upper magnetic cover are integrally formed, and the ferrite is used, the middle column and the lower magnetic cover are integrally formed, and iron powder is used. The coupling coefficient and the anti-current saturation capability of the inductor assembly can be optimized through the above magnetic cores and by using a simple magnetic core machining process and a convenient assembly process.

The inductor assembly shown in this embodiment may also be applied to the voltage regulating device shown in the foregoing embodiments. Similarly, the inductor assembly shown in the foregoing embodiments may also be applied to the voltage regulating device shown in this embodiment, so that the same technical features and advantages may be obtained, and details are not described herein again.

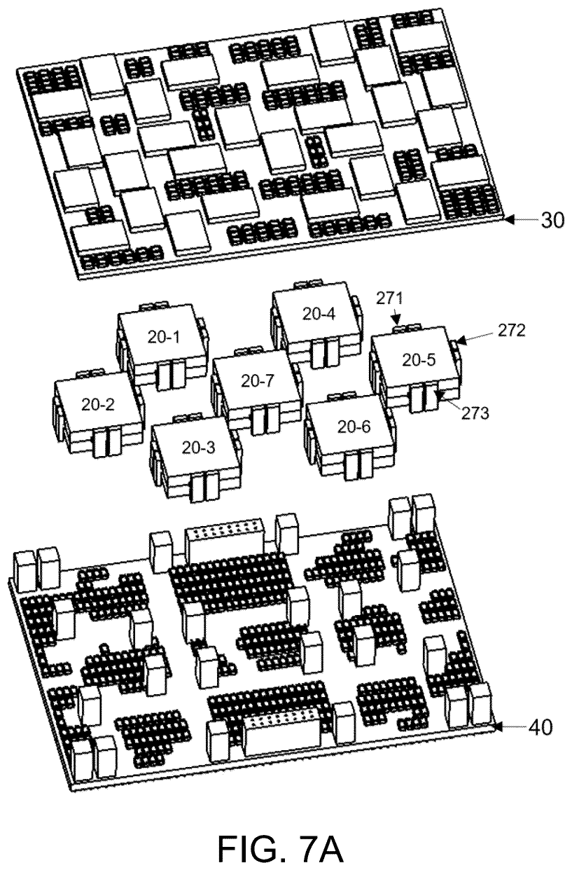

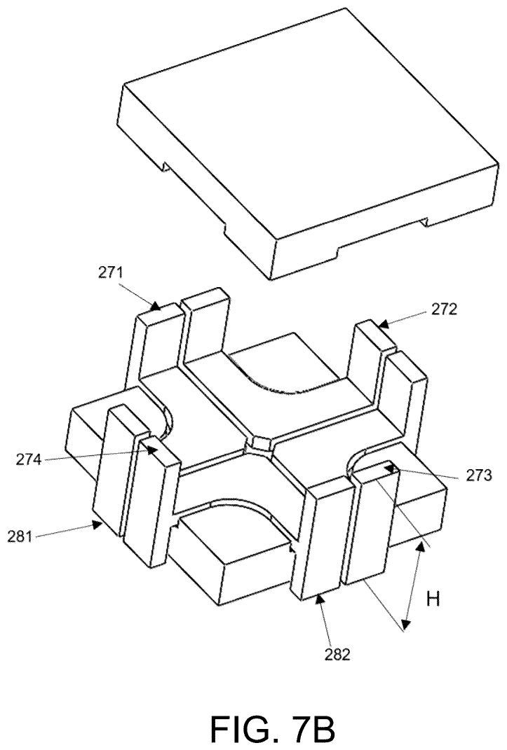

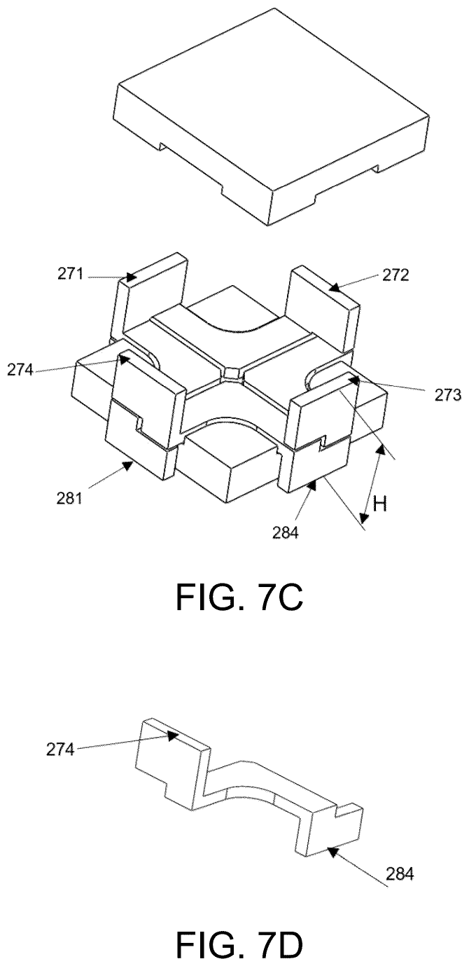

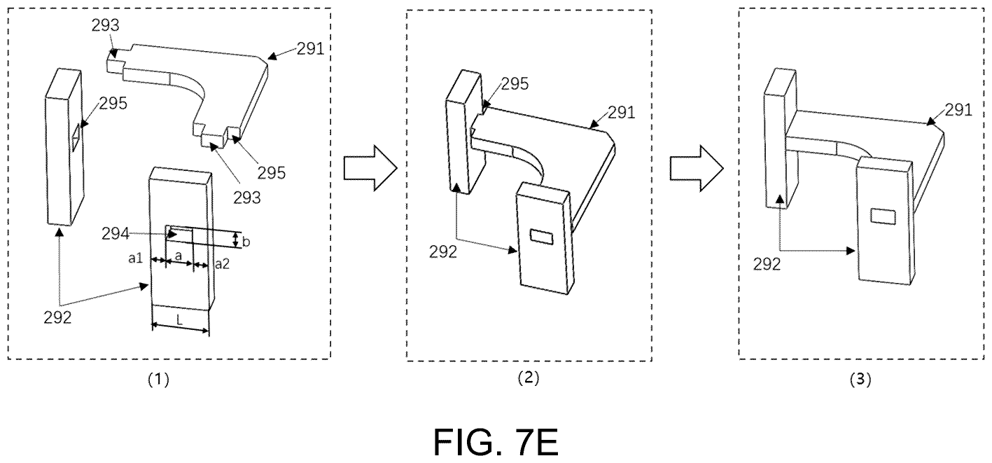

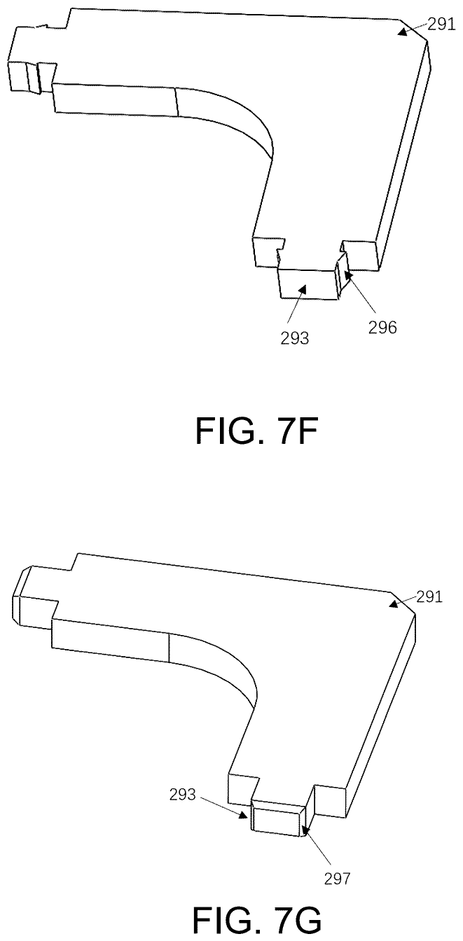

FIGS. 7A and 7B show another configuration of windings that at least one of a SW section or a Vo+ section of each winding extend both upward and downward. For the SW section, it extends upward from the horizontal section of the winding to the first circuit substrate 30 and is fixed and electrically connected with the first circuit substrate 30, and extends downward from the horizontal section to the second circuit substrate 40 and is mechanically connected to the second circuit substrate 40; for the Vo+ section, it extends downward from the horizontal section of the winding to the second circuit substrate 40 and is fixed and electrically connected to the second circuit substrate 40, and extends upward from the horizontal section to the first circuit substrate 30 and is mechanically connected to the first circuit substrate 30. Preferably, a projection of at least one of the SW section or the Vo+ section of the winding in the vertical direction falls within a projection range of the switch bridge arm.

In the device structure shown in the present embodiment, a heat sink is usually provided above the switch bridge arm for dissipating heat generated by the switch bridge arm, and the switch bridge arm and the heat sink achieve heat conduction by means of the heat conduction medium. In order to ensure good contact of the heat conduction medium, the heat sink needs to have a certain pressure on the device. The winding structure shown in the present embodiment can provide a good structural support for the voltage regulating device, and can solve the problem of poor thermal conduction of the heat conduction medium caused by insufficient support force. On the other hand, the thickness of the first circuit substrate 30 is usually lower than 1.5 mm. When the support force is insufficient, the first circuit substrate 30 generates stress deformation, resulting in damage and failure of solder joint on the first circuit substrate 30, resulting in reduced reliability. The winding structure shown in this embodiment can provide sufficient support force for related components in the voltage regulating device, thereby effectively improving the heat dissipation capability and reliability of the voltage regulating device. Furthermore, the winding structure disclosed in the present embodiment can provide a downward heat dissipation channel for the voltage regulating device, that is, the heat generated by the switch bridge arm is directly transferred to the lower winding through the first circuit substrate, and the heat is transferred to the second circuit substrate by using the shortest vertical path, and dissipated outward through the system motherboard, further enhanced the heat dissipation capability of the voltage regulating device. In addition, in this embodiment, the inductor assembly 10 includes a plurality of windings 206, and a first end surface 271/272/273/274 and a second end surface 281/282/283/284 of each winding are respectively fixed and electrically connected to the first circuit substrate and the second circuit substrate. Because a vertical distance H between the first end surface and the second end surface needs to be strictly controlled, a tolerance of the vertical distance H needs to be controlled within a range of +/−100 μm; preferably, the tolerance of the vertical distance H is controlled within +/−50 μm. In the manufacturing process, in order to ensure the tolerance distribution of the vertical distance H, an integral forming process such as high-pressure forging, die casting, or MIM (metal injection molding) process can be used.

FIG. 7C and FIG. 7D show another structure of the winding, and the SW section or Vo+ section of the winding may extend in a horizontal direction, the SW section of each winding and the Vo+ section of the adjacent winding overlap each other in the vertical direction, and the overlapping portions are isolated by an insulating layer, so as to form a support structure, which may have the same technical effect as the winding structure shown in FIG. 7B. The inductor assembly shown in the embodiments may form a winding by means of a sheet metal process, and then form the whole of the inductor assembly by means of a mold injection molding process, and the tolerance of the vertical distance H can be controlled by the height of the mold. Further, a tolerance of the vertical distance H may be further optimized by a process such as milling after the injection molding process structure.

Further, the present application shows a detailed structure and a manufacturing process of the winding as shown in FIG. 7B, as shown in FIGS. 7E to 7G. As shown in FIG. 7E, the H-shaped winding comprises a horizontal section 291 and two vertical sections 292, wherein two ends of the horizontal section 291 are respectively provided with two protruding structures 293; correspondingly, holes 294 are respectively provided on the two vertical sections 292; the cross-sectional area of the protruding structures 293 is similar to the opening size of the holes 294; the cross-sectional area of the protruding structures 293 can also be slightly larger than the opening size of the holes 294, so that the protruding structures and the holes form an interference fit, and the interference rate is in the range of [0.0005, 0.01]×opening sizes. In detail, the length a of the hole 294 is greater than or equal to half of the length L of the vertical section 292, and a longer length a can increase the effective connection area of the protruding structure and the hole, so as to ensure that the winding has a lower connection impedance; the width b of the hole 294 is equal to or approximately equal to the thickness of the horizontal section 291; the wall thicknesses a1 and a2 of the two holes 294 are both greater than or equal to 0.3 mm, so as to ensure that the hole 294 has a certain restraining force on the protruding structure 293; and the length of the protruding structure 293 is in the range of [75%, 125%]×vertical section thickness. Optionally, after the protruding structures 293 passing through the holes 294, the T-type connecting regions 295 on the horizontal sections 291 and the vertical sections 292 are bonded or even welded and interconnected.

The winding parts shown in (1) of FIG. 7E may form the H-windings shown in (3) of FIG. 7E by a direct riveting process. An electrical connection layer may also be provided between the surface of the protruding structure 293 and the surface of the hole 294, the average thickness of the electrical connection layer is less than or equal to 30 μm, preferably less than or equal to 15 μm. The electrical connection layer at least comprises an intermetallic compound of tin (for example, comprising Cu3Sn, Cu6Sn5, and Ni3Sn4); the electrical connection generates a high-temperature intermetallic compound after reflow soldering. Because the melting point of the high-temperature intermetallic compound is greater than 300 degrees Celsius, the H-type winding can be effectively prevented from re-melting in a subsequent reflow soldering process, thereby effectively reducing the displacement, falling off, or H-winding deformation between the horizontal section and the vertical section, thereby ensuring the stability of the size of the H-type winding. Relative to the direct riveting, by providing the electrical connection layer, the contact impedance between the horizontal section and the vertical section can be reduced; and the extremely thin thickness of the electrical connection layer can ensure the extremely low impedance on the connection interface, thereby ensuring the performance and reliability of the inductor assembly.

In addition, in addition to the intermetallic compound of tin, the electrical connection layer may further comprise a tin or tin alloy layer, and the average content of the tin or tin alloy layer is less than or equal to 50% of the electrical connection layer; and while ensuring that the relative displacement between the horizontal section and the vertical section is sufficiently small, the tin alloy has good fluidity and filling performance, so that the connection quality between the horizontal section and the vertical section can be further ensured, and the impedance of the connection interface is reduced. As shown in (1) of FIG. 7E, the T-type connection region 295 between the horizontal section and the vertical section can also be connected through the above electrical connection layer, thereby further reducing the connection impedance between the horizontal section and the vertical section.

In other embodiments, a micro protrusion structure 296 may also be provided on the protruding structure 293, and the micro protrusion structure 296 is provided on a side surface of the protruding structure 293. The mechanical lock between the protruding structure of the horizontal section and the hole of the vertical section is increased. The thickness between the micro protrusion structure 296 and the sidewall metal of the hole is relatively thin, so that a complete intermetallic compound can be formed, and the relative positional relationship between the horizontal section and the vertical section is fixed, so that the position change does not occur during subsequent reflow. In addition, the remaining spaces between the protruding structures 293 and the holes are relatively large, and more tin or tin alloys can be accommodated to form effective caulking, thereby ensuring a lower connection impedance between the two.

In other embodiments, a circle chamfer 297 is provided at a cross-sectional position of the top end of the protruding structure 293, as shown in FIG. 7G, which is convenient for riveting assembling procedures.

The winding structure disclosed in the present application can be plated with tin or tin alloy on the surface of a horizontal section and/or a vertical section, and the thickness of the tin or tin alloy layer is between 3 μm and 15 μm; then the interference fit is completed through the protruding structure and the hole in the horizontal section and the vertical section; and then an electrical connection layer is formed between the two by means of reflow soldering. Optionally, a solder flux is provided in a region where the mechanically assembled winding needs to be welded before reflow soldering, so as to better ensure the connection quality of the electrical connection layer. Optionally, the reflow soldering process can be synchronously completed in a reflow soldering process required for subsequent component assembly, thereby simplifying the process flow. Optionally, when the horizontal section and the vertical section complete an interference fit through the protruding structure and the hole, it is ensured that the T-type connection area 295 between the horizontal section and the vertical section is kept at least partially in contact; and in a subsequent reflow soldering process, the T-type connection area 295 can synchronously implement an electrical connection. Optionally, during the surface treatment of the horizontal section and the vertical section, such as tin plating or a tin alloy, the copper pre-plating layer and/or the nickel anti-diffusion layer can be added; optionally, tin can be plated on the surface of the horizontal section, and a nickel gold layer is plated on the surface of the vertical section, so as to further reduce the tolerance of the vertical section height H. In the above embodiment, the thickness of the copper pre-plating layer is preferably 2 μm to 5 μm, the thickness of the nickel anti-diffusion layer is 1.5 μm to 5 μm, and the gold layer is 0.05 μm to 0.15 μm.

The embodiments shown in FIG. 7A to FIG. 7G may use the technical features of the foregoing embodiments, and may also have the same technical effect. The technical features shown in FIG. 7A to FIG. 7G can also be used with each other to obtain the same technical effect.

The switch tube in switch bridge arm disclosed by the application can be used for realizing the functions of the switch disclosed by the application, such as a Si MOSFET, SiC MOSFET, GaN MOSFET or IGBT MOSFET.

The voltage regulating device according to the above embodiment can also be a part of the electronic device, which can satisfy the technical features and benefits disclosed in the present application.

The “equal” or “same” or “equal to” disclosed by the application needs to consider the parameter distribution of engineering, and the error distribution is within +/−30%; and the included angle between the two line segments or the two straight lines is less than or equal to 45 degrees; the included angle between the two line segments or the two straight lines is within the range of [60, 120]; and the definition of the phase error phase also needs to consider the parameter distribution of the engineering, and the error distribution of the phase error degree is within +/−30%.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A voltage regulating circuit, comprising:
an input positive terminal, an output positive terminal, a ground terminal, N-phase parallel-connected buck circuits, and an additional branch, wherein N is a natural number greater than 1;
each of the N-phase parallel-connected buck circuits comprises a switch bridge arm and an output inductor; N switch bridge arms are electrically connected in parallel between the input positive terminal and the ground terminal, a first terminal of each output inductor is electrically connected to a midpoint of a bridge arm of a corresponding switch bridge arm, and a second terminal of N output inductors are electrically connected to an output positive terminal;
the additional branch comprises N−1 additional windings and a series inductor, the N−1 additional windings and series inductor are sequentially electrically connected in series; a first additional winding is coupled to a first output inductor, a second additional winding is coupled to a second output inductor, a nth additional winding is coupled to a nth output inductor, wherein n is a natural number, and 1≤n≤N−1; the additional branch is electrically connected in parallel with a Nth output inductor.

2. The voltage regulating circuit of claim 1, wherein a first end of each of the additional windings and a first end of the coupled output inductor have the same polarity, and a second end of the (n−1)th additional winding is electrically connected to a first end of the nth additional winding.

3. The voltage regulating circuit of claim 2, wherein the N output inductors are coupled in a same inductor magnetic core.

4. The voltage regulating circuit of claim 2, wherein the nth additional winding and the nth output inductor are coupled in a same inductor magnetic core.

5. The voltage regulating circuit of claim 1, wherein control signals of the N switch bridge arms are sequentially phase-shifted by 360 degrees/N.

6. The voltage regulating circuit of claim 1, wherein a coupling coefficient between the output inductor and the additional winding is any value between 0.5 and 1.

7. The voltage regulating circuit of claim 3, wherein a coupling coefficient of the N output inductors is any value between −1 and 1.

8. An inductor assembly, comprising:
an inductor core and an inductor frame, wherein the inductor core includes an upper magnetic cover, a lower magnetic cover, and at least two magnetic columns,
wherein each of the at least two magnetic column is disposed between the upper magnetic cover and the lower magnetic cover; the inductor frame comprises a top surface, a bottom surface, a first side and a third side opposite to each other, a second side and a fourth side opposite to each other, a winding frame and at least two through grooves; the first side, the second side, the third side and the fourth side are disposed between the top surface and the bottom surface; the through groove penetrates through the top surface and the bottom surface;
the winding frame comprises an inductor winding and an additional winding, and the main body of the inductor winding and the main body of the additional winding are wound along the same path;
the inductor frame further includes an electrical connector Vo+, an electrical connector SW, and an electrical connector Sig; the electrical connector Vo+, the electrical connector SW, and the electrical connector Sig are all disposed adjacent to the side surface of the inductor frame; the electrical connector Vo+ forms a Vo+ end portion on the bottom surface of the inductor frame, the electrical connector SW forms a SW end portion on the top surface of the inductor frame, and the electrical connector Sig forms a Sig end portion on the top surface and/or the bottom surface of the inductor frame;
a first end of the inductor winding is electrically connected to an electrical connector SW, a second end of the inductor winding is electrically connected to an electrical connector Vo+, and a first end and a second end of the additional winding are electrically connected to one electrical connector Sig, respectively;
the magnetic column of the inductor magnetic core passes through the through groove, and the upper magnetic cover and the lower magnetic cover are respectively buckled with the winding frame from the top surface and the bottom surface.

9. The inductor assembly of claim 8, wherein the inductor frame further comprises a blind groove recessed from a bottom surface of the inductor frame to the winding frame.

10. The inductor assembly of claim 9, wherein a depth of the blind groove is greater than or equal to a thickness of the lower magnetic cover.

11. The inductor assembly of claim 8, wherein the inductor frame further comprises an independent electrical connector,
wherein one end of the independent electrical connector is fixed on the bottom surface of the inductor frame, the other end of the independent electrical connector is fixed and electrically connected to other components, and the independent electrical connector is configured to transmit power, control signals, or sampling signals.

12. The inductor assembly of claim 11, wherein the independent electrical connector is a copper block.

13. The inductor assembly of claim 8, wherein the inductor frame further comprises an electrical connector GND, and the electrical connector GND forms a GND end portion at a top surface and a bottom surface of the inductor frame, respectively.

14. The inductor assembly of claim 13, wherein the inductor magnetic core comprises two magnetic columns, the through groove is two, and the one inductor winding and the additional winding pass between the two through grooves; the electrical connector GND is disposed on the first side of the inductor frame, the electrical connector Vo+ is disposed adjacent to the third side of the inductor frame, the electrical connector SW is disposed adjacent to the first side of the inductor frame, and the electrical connector Sig is disposed adjacent to the first side and/or the third side of the inductor frame.

15. The inductor assembly of claim 13, wherein the inductor magnetic core comprises four magnetic columns, the through groove is four, and the inductor assembly comprises four inductor windings and three additional windings; the one inductor winding and the coupled one additional winding are wound around a through groove; the electrical connector GND, the electrical connector Vo+, the electrical connector SW, and the electrical connector Sig are all disposed adjacent to the first side and the third side of the inductor frame.

16. The inductor assembly of claim 15, wherein the inductor magnetic core further comprises a middle column, the inductor frame further comprises a middle column through groove, and the middle column passes through the middle column through groove.

17. The inductor assembly of claim 13, wherein the electrical connector GND, the electrical connector SW, the electrical connector Sig and the electrical connector Vo+ are implemented by punching, lateral plating or embedded copper blocks.

18. The inductor assembly of claim 13, wherein the electrical connector GND is disposed on the first side and/or the third side of the inductor frame.

19. The inductor assembly of claim 8, wherein the inductor frame is implemented by a printed circuit board.

20. The inductor assembly of claim 8, wherein one magnetic cover of the inductor magnetic core is a high magnetic permeability material, the other magnetic cover is a low magnetic permeability material, and a ratio of the high magnetic permeability to the low magnetic permeability is greater than 5.

21. An inductor assembly, comprising:
an upper magnetic cover, a lower magnetic cover, a plurality of winding columns and a plurality of inductor windings,
wherein each inductor winding includes a horizontal winding section and two vertical sections, the two vertical section are a SW section and a Vo+ section, respectively; the upper magnetic cover and the lower magnetic cover are relatively buckled to form a magnetic core, the magnetic core comprises a top surface, a bottom surface and four side surfaces, each horizontal winding section is wound around a winding column respectively between the upper magnetic cover and the lower magnetic cover, and the SW section and the Vo+ section of each inductor winding are respectively disposed on two adjacent side surfaces of the magnetic core; the Vo+ section of each inductor winding is disposed adjacent to the SW section of the next inductor winding; the two ends of the horizontal winding section are respectively provided with two protrusions, the two vertical sections are both provided with through holes, and the two protrusions are cooperatively connected to the through holes.

22. The inductor assembly of claim 21, wherein a length of the through hole is greater than or equal to half of a length of the vertical section, and a thickness of the through hole is approximately equal to a thickness of the horizontal winding section.

23. The inductor assembly of claim 21, wherein an electrical connection layer is disposed between a surface of the protrusion and a surface of the through hole.

24. The inductor assembly of claim 21, wherein a side surface of the protrusion is provided with a micro-protrusion structure.

25. The inductor assembly according to claim 21, wherein a top end of each of the two protrusions is provided with a chamfer.

26. The inductor assembly of claim 21, wherein the upper magnetic cover and the lower magnetic cover respectively adopt a high magnetic permeability material and a low magnetic permeability material, and a ratio of the high magnetic permeability to the low magnetic permeability is greater than 5.

27. The inductor assembly of claim 21, wherein the inductor assembly further comprises a middle column, the middle column is disposed among a plurality of winding columns, the horizontal winding section is disposed between the middle column and the winding column.

28. The inductor assembly of claim 27, wherein the winding column and the middle column are integrally formed with the upper magnetic cover, and the winding column, the middle column and the upper magnetic cover are made of the same magnetic permeability material, and the lower magnetic cover is made of a different magnetic permeability material;
or, the winding column, the middle column and the lower magnetic cover are integrally formed, the winding column, the middle column and the lower magnetic cover are made of the same magnetic permeability material, and the upper magnetic cover is made of a different magnetic permeability material;
alternatively, the winding columns are integrally formed with one of the magnetic covers, and a first magnetic permeability material is adopted, the middle column is integrally formed with the other magnetic cover, and a second magnetic permeability material is adopted, and the magnetic permeability of the first magnetic permeability material is different from that of the second magnetic permeability material.

29. A voltage regulating device, comprising:
a first circuit substrate, a second circuit substrate, and an inductor assembly;
wherein the first circuit substrate comprises a through groove, a first pad region, an upper surface and a lower surface opposite to each other, the through groove penetrates through the upper surface and the lower surface, and the first pad region is disposed on the lower surface of the first circuit substrate; the second circuit substrate comprises a second pad region, an upper surface and a lower surface opposite to each other, and the second pad region is disposed on the upper surface of the second circuit substrate;
the inductor assembly comprises an inductor magnetic core, a top surface and a bottom surface opposite to each other, wherein the top surface is provided with at least one top surface end portion, and the bottom surface is provided with at least one bottom surface end portion; the top surface end portion is fixed in the first pad region and is electrically connected to the first circuit substrate; the bottom surface end portion is fixed in the second pad region and is electrically connected to the second circuit substrate; the top surface of the inductor magnetic core is exposed from the top surface of the voltage regulating device by means of a through groove;
wherein the voltage regulating device further comprises a switch bridge arm and a BGA array, the switch bridge arm is disposed on the upper surface of the first circuit substrate, the switch bridge arm is electrically connected to the top surface end portion through the first circuit substrate and the first pad region; the BGA array is disposed on the lower surface of the second circuit substrate, the BGA array is electrically connected to the bottom surface end portion through the second circuit substrate and the second pad region.

30. The voltage regulating device of claim 29, wherein vertical projections of the switch bridge arm and the inductor magnetic core on the same horizontal plane do not overlap.

31. The voltage regulating device of claim 29, wherein the top surface end portion is a SW end portion, and the SW end portion is electrically connected to a midpoint of a bridge arm of the switch bridge arm; the bottom surface end portion is a Vo+ end portion, and the Vo+ end portion is electrically connected to a portion of the BGA array.

32. The voltage regulating device of claim 31, wherein the inductor assembly further comprises an electrical connector GND, the electrical connector GND is disposed on a side surface of the inductor assembly by side copper plating, and a GND end portion is formed on the top surface and the bottom surface of the inductor assembly.

33. The voltage regulating device of claim 31, wherein the inductor assembly further comprises an electrical connector Sig, and the electrical connector Sig forms a Sig end portion on the top surface and/or the bottom surface of the inductor assembly.

34. The voltage regulating device of claim 33, further comprising a series inductor disposed adjacent to the inductor assembly and electrically connected to the Sig end portion.

35. The voltage regulating device of claim 29, further comprising an independent electrical connector, wherein one end of the independent electrical connector is fixed to and electrically connected to the first circuit substrate, and the other end of the independent electrical connector is fixed to and electrically connected to the second circuit substrate.

36. The voltage regulating device of claim 29, further comprising an input capacitor, wherein the input capacitor is disposed on the upper surface and/or the lower surface of the first circuit substrate.

37. The voltage regulating device of claim 29, further comprising an output capacitor, wherein the output capacitor is disposed on the upper surface of the second circuit substrate.

38. The voltage regulating device of claim 37, wherein the output capacitor is disposed on the upper surface of the second circuit substrate and corresponds to a lower surface of the inductor assembly.

39. A voltage regulating device, comprising:
at least three voltage regulating units, which are a left-side voltage regulating unit, an intermediate voltage regulating unit and a right-side voltage regulating unit, respectively;
wherein each of the voltage regulating units comprises a bridge arm unit, an inductor assembly and a BGA unit, and the bridge arm unit, the inductor assembly and the BGA unit in each of the voltage regulating units are electrically connected;
the bridge arm unit, the inductor assembly, and the BGA unit of the left-side voltage regulating unit are sequentially stacked in a vertical direction; the bridge arm unit, the inductor assembly, and the BGA unit of the right-side voltage regulating unit are sequentially stacked in a vertical direction; the bridge arm unit and the inductor assembly of the intermediate voltage regulating unit are stacked in a vertical direction; the bridge arm unit of the intermediate voltage regulating unit is arranged between the left side bridge arm unit and the right side bridge arm unit, the inductor assembly of the intermediate voltage regulating unit is arranged between the inductor assembly of the left side voltage regulating unit and the inductor assembly of the right side voltage regulating unit; the BGA unit of the intermediate voltage regulating unit surrounds the BGA unit of the left side voltage regulating unit and the BGA unit of the right side voltage regulating unit.

40. The voltage regulating device of claim 39, further comprising a first circuit substrate and a second circuit substrate, wherein the first circuit substrate and the second circuit substrate both comprise an upper surface and a lower surface opposite to each other; the bridge arm unit is disposed on the upper surface of the first circuit substrate, the inductor assembly is disposed between the lower surface of the first circuit substrate and the upper surface of the second circuit substrate, and the bridge arm unit and the inductor assembly are electrically connected through the first circuit substrate;
the BGA unit is disposed on the lower surface of the second circuit substrate, and the inductor assembly and the BGA unit are electrically connected through the second circuit substrate.

41. The voltage regulating device of claim 40, wherein the bridge arm unit comprises four switch bridge arms, each of the switch bridge arms comprises a pin SW and a pin Sig, and the pin SW and the pin Sig are arranged on two opposite sides of each switch bridge arm; the inductor assembly includes a magnetic core and a winding, a vertical projection plane of the magnetic core is on a horizontal plane where the bridge arm unit is located, and each of the pins SW is disposed along an outer side of the vertical projection plane.

42. The voltage regulating device of claim 41, wherein the four switch bridge arms are respectively a first switch bridge arm, a second switch bridge arm, a third switch bridge arm, and a fourth switch bridge arm, the pins Sig of the first switch bridge arm and the third switch bridge arm are arranged adjacent to each other, and both are in the vertical projection plane; and the pins Sig of the second switch bridge arm and the third switch bridge arm are both arranged outside the vertical projection plane.

43. The voltage regulating device of claim 40, further comprising a Vin+ electrical connector, a GND electrical connector, and a Sig electrical connector; the Vin+ electrical connector, the GND electrical connector and the Sig electrical connector are disposed between the first circuit substrate and the second circuit substrate and are used for transferring power and signals between the first circuit substrate and the second circuit substrate; the Vin+ electrical connector is disposed adjacent to four corners of the area where the BGA unit is disposed; each of the Vin+ electrical connectors is adjacent to a GND electrical connector;
wherein the voltage regulating device further comprising a Vin+ unit, the Vin+ unit is disposed on the lower surface of the second circuit substrate, and a projection of each of the Vin+ electrical connectors on the lower surface of the second circuit substrate at least partially overlaps the Vin+ unit.

44. The voltage regulating device of claim 39, wherein the voltage regulating device comprises three left-side voltage regulating units and three right-side voltage regulating units, the three left-side voltage regulating units are arranged adjacent to each other, and the three right-side voltage regulating units are arranged adjacent to each other.

45. The voltage regulating device of claim 44, wherein the seven bridge arm units adopt the same layout structure.

46. A voltage regulating device, comprising:
a bridge arm unit and an inductor assembly, wherein the bridge arm unit and the inductor assembly are electrically connected and stacked in a vertical direction;
wherein the bridge arm unit includes a first switch bridge arm, a second switch bridge arm, a third switch bridge arm, and a fourth switch bridge arm, each of the switch bridge arms includes a pin SW;
wherein the inductor assembly comprises a magnetic core and a winding; a vertical projection plane of the magnetic core is on the horizontal plane where the bridge arm unit is located, and each pin SW is arranged along the outer sides of the vertical projection plane.

47. The voltage regulating device of claim 46, further comprising a BGA unit electrically connected to the inductor assembly, the bridge arm unit, the inductor assembly, and the BGA unit are stacked in a vertical direction.

48. The voltage regulating device of claim 47, further comprising a first circuit substrate and a second circuit substrate, wherein the first circuit substrate and the second circuit substrate both comprise an upper surface and a lower surface opposite to each other; the bridge arm unit is disposed on the upper surface of the first circuit substrate, the inductor assembly is disposed between the first circuit substrate and the upper surface of the second circuit substrate, and the bridge arm unit and the inductor assembly are electrically connected through the first circuit substrate; the BGA unit is disposed on the lower surface of the second circuit substrate, and the inductor assembly and the BGA unit are electrically connected through the second circuit substrate;
wherein the voltage regulating device further comprising a Vin+ electrical connector, a GND electrical connector, and a Sig electrical connector; the Vin+ electrical connector, the GND electrical connector and the Sig electrical connector are disposed between the first circuit substrate and the second circuit substrate and are used for transferring power and signals between the first circuit substrate and the second circuit substrate; the Vin+ electrical connector is disposed adjacent to four corners of the area where the BGA unit is disposed; each of the Vin+ electrical connectors is adjacent to a GND electrical connector;
wherein the voltage regulating device further comprising a Vin+ unit, the Vin+ unit is disposed on the lower surface of the second circuit substrate, and a projection of each of the Vin+ electrical connectors on the lower surface of the second circuit substrate at least partially overlaps the Vin+ unit.

49. The voltage regulating device of claim 46, each switch bridge arm comprises a pin Sig, the pins Sig and the pin SW are arranged on the two opposite sides of each switch bridge arm; the pins Sig of the first switch bridge arm and the third switch bridge arm are arranged adjacent to each other, and both are in the vertical projection plane; the pins Sig of the second switch bridge arm and the third switch bridge arm are both arranged outside the vertical projection plane.
